(19) United States
(12) Patent Application Publication
(10) Pub. No.: US 2022/0145017 A1
(43) Pub. Date: May 12, 2022

(54) METHOD AND SYSTEM FOR GENERATING A POLYMER-PEROVSKITE HYBRID

(71) Applicants: Vivek MAHESHWARI, Waterloo (CA); Rohit SARAF, Waterloo (CA)

(72) Inventors: Vivek MAHESHWARI, Waterloo (CA); Rohit SARAF, Waterloo (CA)

(21) Appl. No.: 17/433,393

(22) PCT Filed: Feb. 25, 2020
(86) PCT No.: PCT/CA2020/050237

§ 371 Date: Aug. 24, 2021

Related U.S. Application Data
(60) Provisional application No. 62/919,023, filed on Feb. 25, 2019.

(51) Int. Cl. C08J 3/21; C08K 3/16; H01L 51/42

(52) U.S. Cl. CPC C08J 3/21; C08K 3/16; C08K 2003/164; C08J 2325/06; H01L 51/4213

(57) ABSTRACT

The disclosure is directed at a method and system for generating a polymer-perovskite hybrid (PPH). The PPH can then be used in the manufacture of a final product, such as a solar cell or photon detectors. The PPH is generated by the mixing of a precursor solution including a Lewis acid chemical component and a cation component with a polymer. The mixture is then synthesized to generate the PPH.

### CROSS-REFERENCE TO OTHER APPLICATIONS

The current application claims priority from U.S. Provisional Application No. 62/919,023 filed Feb. 25, 2019, which is hereby incorporated by reference.

### FIELD

The disclosure is generally directed at material composition and, more specifically, at a method and system for generating a polymer-perovskite hybrid.

### BACKGROUND

The push to use renewable resources continues to steadily grow as concern for the environment grows. Different ways to harness renewable energy are continually being developed. This includes innovation in the field of solar energy. Solar energy cells are being developed to assist in converting photons from the sun into electricity.

The poor stability of organic-inorganic hybrid perovskites, such as MAPbI₃, that leads to a loss of performance in optoelectronic devices has become one of the biggest obstacles for their commercial viability. The Lewis acid-base adduct approach by the choice of proper solvents and their interaction with the precursor PbI₂ (a known Lewis acid) has been an effective methodology for making high quality perovskite films such as those of MAPbI₃ with large grain size, better crystallinity and long carrier lifetimes and this has led to a simple fabrication and synthesis process. However, the challenge of stability under normal operating conditions still needs to be addressed using a simple approach. Though strategies such as, incorporating a barrier layer or interfacial layer made of specialty chemicals, complex formation, encapsulation of the device, altering the constituting ions in the perovskite, additives, and polymer doping have been used to this effect, but limitations arise as they require the use of inert operating conditions or indirect exposure of the perovskite layer to illumination and ambient environment or apply specialty chemicals and extra processing steps. A primary reason for this is that the strategies do not use any specific interactions between the added species and the constituting ions of the perovskite to limit the degradation.

Therefore, there is provided a novel method and system for generating a polymer-perovskite hybrid.

### SUMMARY

The disclosure is directed at a method and system for generating a polymer-perovskite hybrid. The polymer-perovskite hybrid of the disclosure provides a stable material that can be used in the fabrication of other products, such as, but not limited to, solar cells.

In one aspect of the disclosure, there is provided a method of manufacturing a polymer-perovskite hybrid including obtaining a pre-cursor solution; mixing the pre-cursor solution with a polymer solution to generate a mixture; and synthesizing the mixture to manufacture the polymer-perovskite hybrid.

In another aspect, obtaining the pre-cursor solution includes obtaining a Lewis acid chemical component liquid solution; obtaining a cation liquid solution by dissolving a cation component in a liquid; and mixing the cation liquid solution with the Lewis acid chemical component liquid solution. In another aspect, obtaining the Lewis acid chemical component includes dissolving a Lewis acid in a liquid. In a further aspect, the Lewis acid is lead iodide, tin chloride, tin iodide, aluminum chloride, aluminum halides, lead bromide or lead chloride. In yet another aspect, the cation component is from methylammonium iodide, methylammonium bromide, cesium iodide or formamidinium iodide or a combination of thereof. In yet a further aspect, the polymer is polystyrene, polyvinyl chloride, or polysulfone. In another aspect, the polystyrene is polystyrene chains.

In another aspect of the disclosure, there is provided a method of manufacturing a solar cell including synthesizing a polymer-perovskite hybrid, the polymer-perovskite hybrid manufactured by: obtaining a pre-cursor solution; mixing the pre-cursor solution with a polymer solution to generate a mixture; and synthesizing the mixture to manufacture the polymer-perovskite hybrid.

In yet another aspect, obtaining a pre-cursor solution includes obtaining a Lewis acid chemical component liquid solution; obtaining a cation liquid solution by dissolving at least one cation component in a liquid; and mixing the cation liquid solution with the Lewis acid chemical component liquid solution.

In another aspect, obtaining the Lewis acid chemical component includes dissolving a Lewis acid in a liquid. In yet another aspect, the Lewis acid is lead iodide, aluminum chloride, aluminum halides, lead bromide, lead chloride, tin iodide, tin chloride or tin bromide. In yet a further aspect, the cation component is from methylammonium iodide, methylammonium bromide, cesium iodide or formamidinium iodide. In an aspect, the polymer is polystyrene, polyvinyl chloride, or polysulfone.

In another aspect of the disclosure, there is provided a polymer-perovskite hybrid including a polymer; a Lewis acid chemical component that interacts with the polymer and can cross-link with the polymer; and a cation component that interacts with π-electrons of the polymer.

In yet another aspect, the Lewis acid chemical component is lead iodide, lead bromide, lead chloride, tin iodide, tin chloride or tin bromide. In yet a further aspect, the cation component is a salt cation from methylammonium iodide, methylammonium bromide, cesium iodide or formamidinium iodide.

### DESCRIPTION OF THE DRAWINGS

Embodiments of the present disclosure will now be described, by way of example only, with reference to the attached Figures.

FIG. 1a is a flowchart outlining a method of generating a polymer-perovskite hybrid;

FIG. 1b is a schematic diagram of a polymer-perovskite hybrid;

FIG. 1c is a flowchart outlining a method of generating a pre-cursor solution;

FIG. 1d is a set of diagrams showing benefits of the polymer-perovskite hybrid of the disclosure;

FIG. 2a is a graph showing gel permeation chromatography refractive index traces for different samples in THF with respect to cross-linking of the polystyrene within MAPbI3;

FIG. 2b is a graph showing a 1 hr NMR spectra of the 1 wt % PS solution and 1 wt % PS—PbI2 solution collected in DMF-d7 and DMSO-d6 (magnification of the scale between 6.2 and 7.6 ppm) with respect to cross-linking of the polystyrene within MAPbI3 and the device configuration;

FIG. 2c is a schematic diagram of the architecture of a solar cell with respect to cross-linking of the polystyrene within MAPbI3;

FIG. 2d is a cross-sectional SEM image of a complete solar cell;

FIG. 2e is a graph showing a 1H NMR spectra of the 1 wt % PS solution with and without PbI₂ collected in deuterated N, N-dimethylformamide-d7 (DMF-d7) and Dimethylsulfoxide-d6 (DMSO-d6) at a low magnification scale between 0.5 and 8.5 ppm;

FIG. 2f is a graph showing a 1H NMR spectra of the 1 wt % PS solution with and without PbI₂ collected in deuterated N, N-dimethylformamide-d7 (DMF-d7) and Dimethylsulfoxide-d6 (DMSO-d6) at a high magnification scale between 0.8 and 2.5 ppm;

FIG. 2g is a graph showing detection of the hydrogen (H2) evolved from the reaction mixture;

FIG. 2h is a schematic diagram of an energy level diagram of the perovskite solar cells;

FIG. 2i is a graph showing J-V curves of the pure MAPbI₃, PS-MAPbI₃ with different concentrations, and S-MAPbI₃ devices without HTL under one sun illumination;

FIG. 2j is a graph showing J-V characteristics of the pure MAPbI₃, PS-MAPbI₃ with different concentrations, and S-MAPbI₃ devices without HTL in dark;

FIG. 3a is a graph showing J-V curves of the pure MAPbI₃, 1 and 14 wt % PS-MAPbI₃, and S-MAPbI₃ devices with HTL under one sun illumination with respect to the effect of cross-linked PS chains on the perovskite photovoltaics performance and crystal structure;

FIG. 3b is a graph showing J-V characteristics of the pure MAPbI₃ and 1 wt % PS-MAPbI₃ solar cells under the reverse and forward scan directions with respect to effect of cross-linked PS chains on the perovskite photovoltaics performance and crystal structure;

FIG. 3c is a graph showing XRD patterns with inset showing the increase in diffraction intensity with PS content with respect to effect of cross-linked PS chains on the perovskite photovoltaics performance and crystal structure;

FIG. 3d is a graph showing Raman spectra with respect to effect of cross-linked PS chains on the perovskite photovoltaics performance and crystal structure FIG. 3e is an enlarged view of the Raman spectra graph of FIG. 3d from 20-400 cm-1 for pure MAPbI₃, 1 and 14 wt % PS-MAPbI₃, and 14 wt % S-MAPbI₃ films with respect to effect of cross-linked PS chains on the perovskite photovoltaics performance and crystal structure;

FIG. 3f is a graph showing photovoltaic performance of the pure MAPbI₃, 1 and 14 wt % PS-MAPbI₃, and 14 wt % S-MAPbI₃ devices with and without HTL;

FIG. 3g is a graph showing energy band gap spectra for pure MAPbI₃, 1 and 14 wt % PS-MAPbI₃, and 14 wt % S-MAPbI₃ films;

FIG. 3h is a graph showing a magnified view of Raman spectra for pure MAPbI₃, 1 and 14 wt % PS-MAPbI₃, and 14 wt % S-MAPbI₃ films at 50-130 cm⁻¹ wave numbers;

FIG. 3i is a graph showing a magnified view of Raman spectra for pure MAPbI₃, 1 and 14 wt % PS-MAPbI₃, and 14 wt % S-MAPbI₃ films at 135-160 cm⁻¹ wave numbers;

FIG. 3j is a graph showing a magnified view of Raman spectra for pure MAPbI₃, 1 and 14 wt % PS-MAPbI₃, and 14 wt % S-MAPbI₃ films at 180-360 cm⁻¹ wave numbers;

FIG. 3k is a graph showing current-response measured from a vertical device configuration of ITO/PS-MAPbI₃ (or MAPbI₃)/Au at 0.05 V;

FIG. 4a is a graph showing XRD patterns of MAPbI₃ films after exposing them under continuous one-sun illumination in ambient environment with 40-50% relative humidity for different times with respect to stability characterization of perovskite solar cells;

FIG. 4b is a graph showing XRD patterns of 1 wt % PS-MAPbI₃ films after exposing them under continuous one-sun illumination in ambient environment with 40-50% relative humidity for different times with respect to stability characterization of perovskite solar cells;

FIG. 4c is a graph showing Raman spectra of MAPbI₃ and 1 wt % PS-MAPbI₃ films after incessant light and moisture exposure with respect to stability characterization of perovskite solar cells;

FIG. 4d is a graph showing operational stability of the cells examined at maximum power point with a constant bias of 0.80 V for MAPbI₃ and 0.86 V for 1 wt % PS-MAPbI₃ devices with HTL under continuous full-sun illumination in air and moisture at 45° C. with respect to stability characterization of perovskite solar cells;

FIG. 4e is a graph showing normalized PCEs for the pure MAPbI₃, 1 and 14 wt % PS-MAPbI₃, and 14 wt % S-MAPbI₃ solar cells without HTL after ageing continuously in full sun illumination, ambient air at 45° C., and 40-50% relative humidity for 1008 h (42 days) with respect to stability characterization of perovskite solar cells;

FIG. 4f is a graph showing normalized PCEs for the pure MAPbI₃, and 1 wt % PS-MAPbI₃ solar cells with HTL under the same testing conditions as in FIG. 4e with respect to stability characterization of perovskite solar cells;

FIG. 5a is a graph showing normalized V_{oc}, for the pure MAPbI₃, 1 and 14 wt % PS-MAPbI₃, and 14 wt % S-MAPbI₃ solar cells without HTL after ageing under continuous full-sun (AM 1.5 G) illumination in ambient air with 40-50% relative humidity;

FIG. 5b is a graph showing normalized J_{sc}, for the pure MAPbI₃, 1 and 14 wt % PS-MAPbI₃, and 14 wt % S-MAPbI₃ solar cells without HTL after ageing under continuous full-sun (AM 1.5 G) illumination in ambient air with 40-50% relative humidity;

FIG. 5c is a graph showing normalized FF, for the pure MAPbI₃, 1 and 14 wt % PS-MAPbI₃, and 14 wt % S-MAPbI₃ solar cells without HTL after ageing under continuous full-sun (AM 1.5 G) illumination in ambient air with 40-50% relative humidity;

FIG. 6a is a graph showing normalized V_{oc}, for the pure MAPbI₃, and 1 wt % PS-MAPbI₃ solar cells with HTL after exposing in ambient air with 40-50% relative humidity and under continuous full-sun (AM 1.5 G) illumination;

FIG. 8b is a graph showing normalized J_{sc}, for the pure MAPbI₃, and 1 wt % PS-MAPbI₃ solar cells with HTL after exposing in ambient air with 40-50% relative humidity and under continuous full-sun (AM 1.5 G) illumination;

FIG. 8c is a graph showing normalized FF, for the pure MAPbI₃, and 1 wt % PS-MAPbI₃ solar cells with HTL after exposing in ambient air with 40-50% relative humidity and under continuous full-sun (AM 1.5 G) illumination;

FIG. 7 is a table showing a comparison of the stability of organic-inorganic hybrid perovskite solar cells with various device configurations under different conditions;

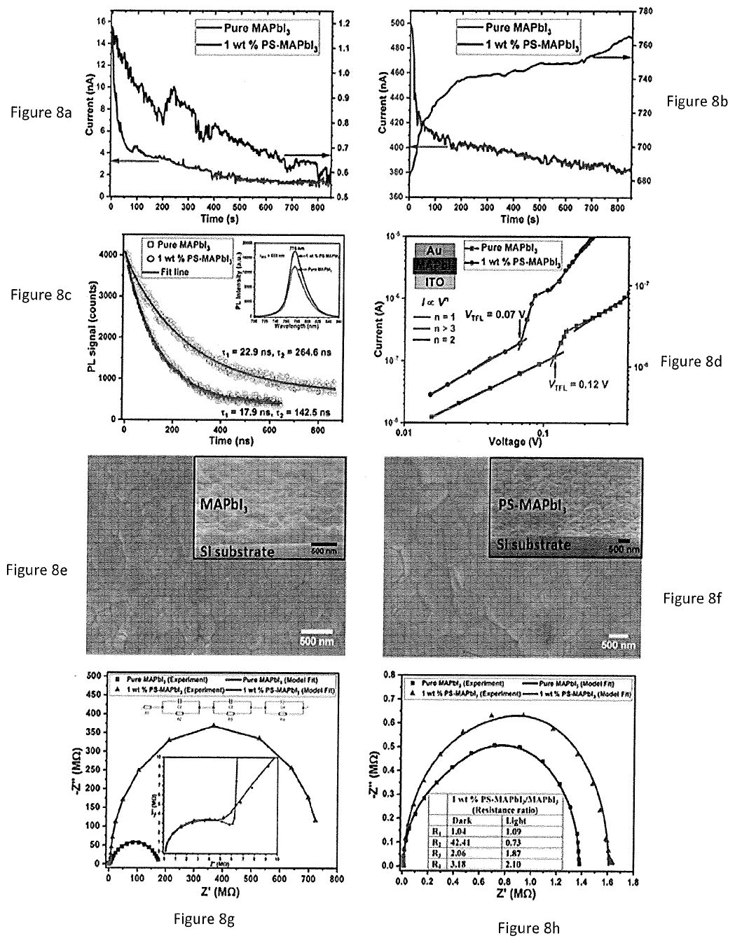

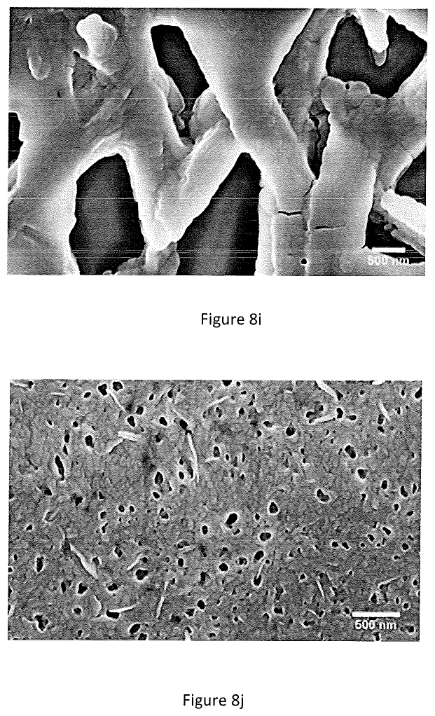

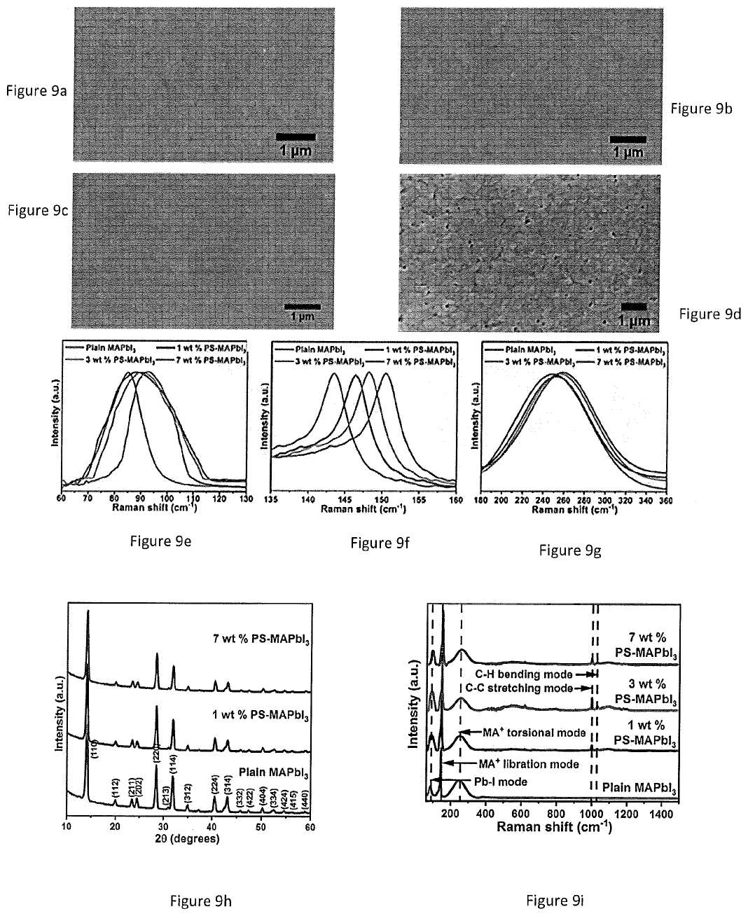

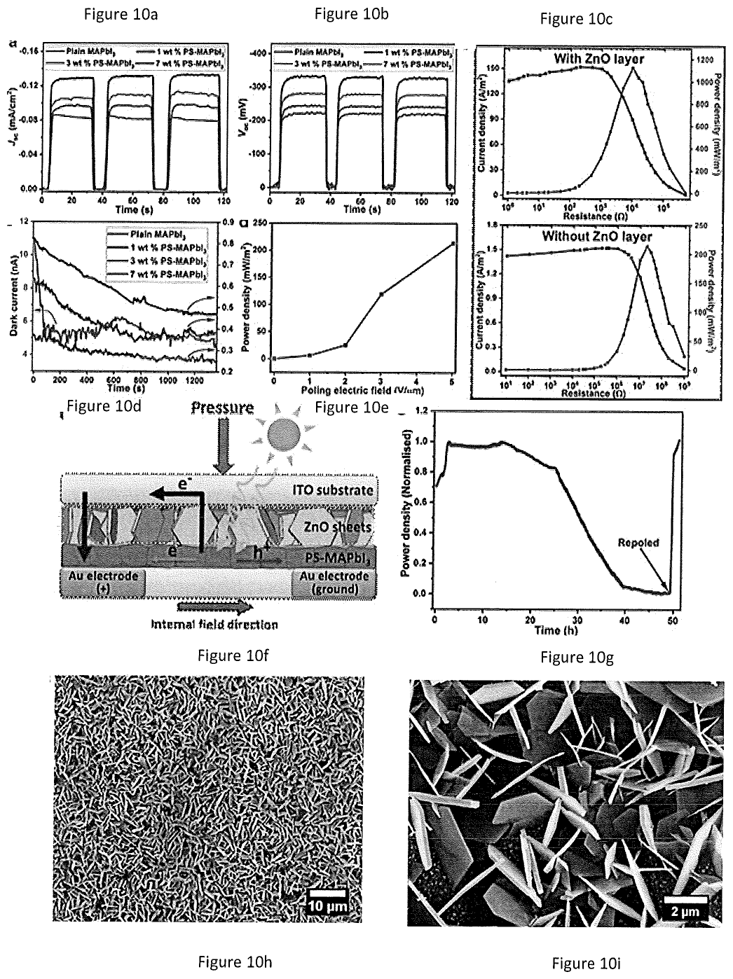

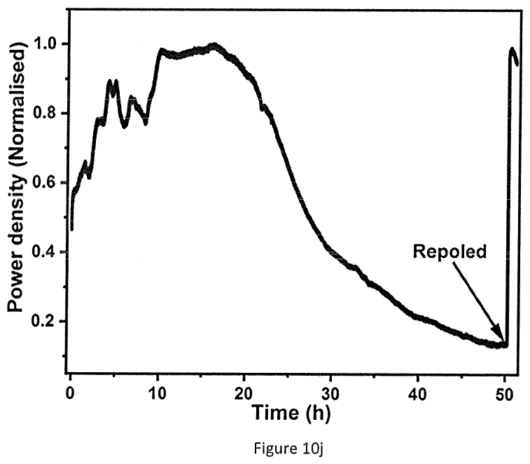

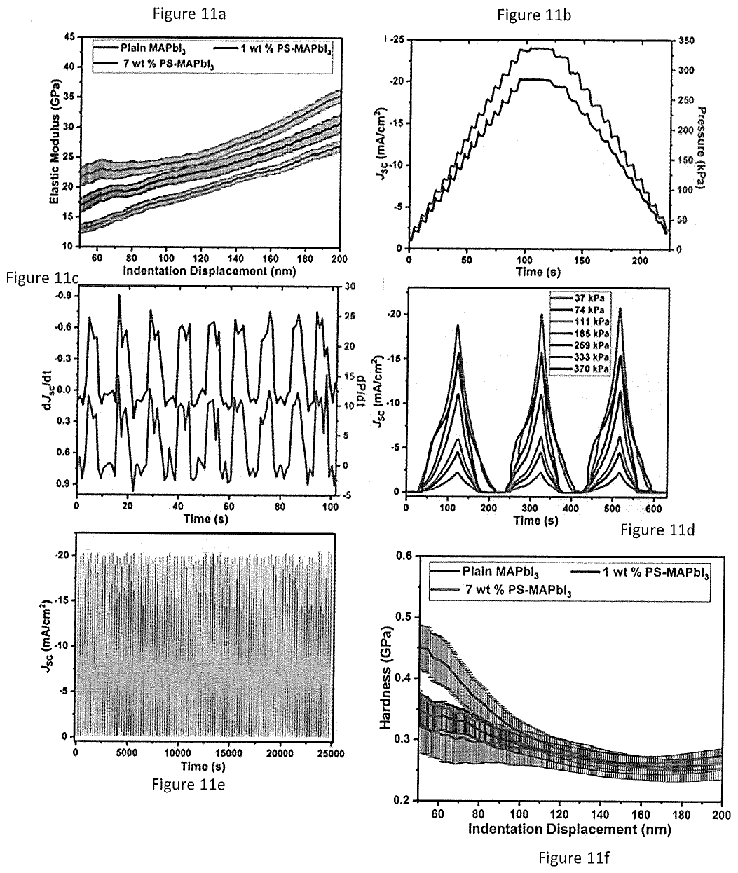

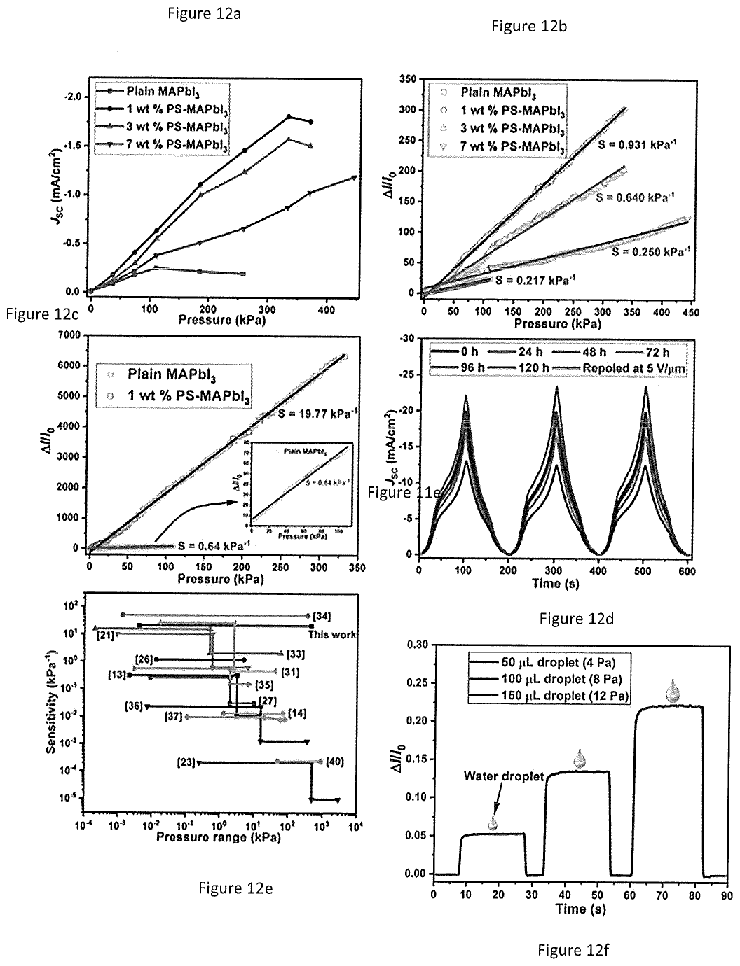

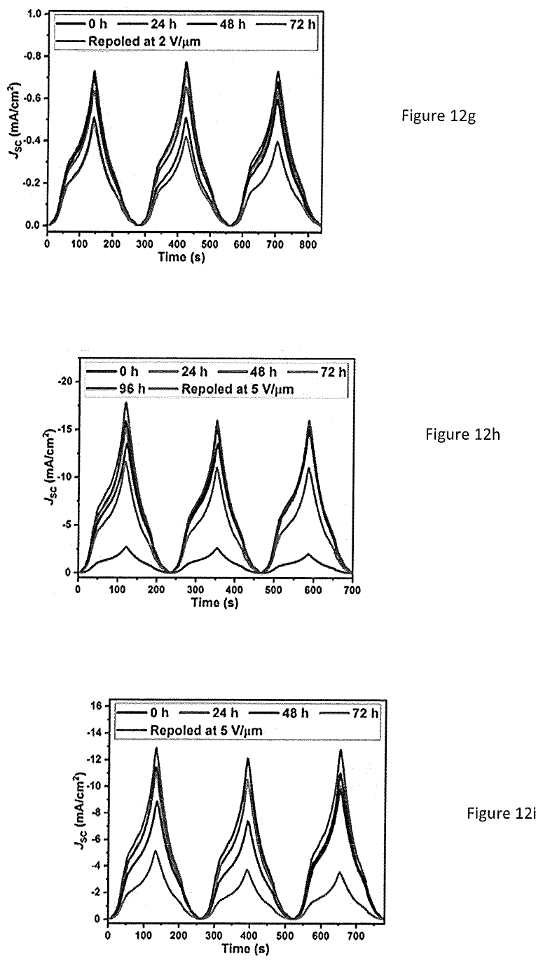

FIG. 8a is a graph showing a current response under dark illumination from a symmetric lateral Au/PS-MAPbI₃ (or MAPbI₃)/Au device structure at 5 V with respect to the role of cross-linked PS in improving stability and enhancing performance of perovskite solar cells;

FIG. 8b is a graph showing a current response under light illumination from a symmetric lateral Au/PS-MAPbI₃ (or MAPbI₃)/Au device structure at 5 V with respect to the role of cross-linked PS in improving stability and enhancing performance of perovskite solar cells;

FIG. 8c is a graph of a time-resolved photoluminescence (TRPL) decay spectra of MAPbI₃ and 1 wt % PS-MAPbI₃ films, with the inset showing the steady-state PL spectra;

FIG. 8d is a graph showing dark I-V measurements of MAPbI₃ and 1 wt % PS-MAPbI₃ films exhibiting different regions, with the inset illustrating the device structure;

FIG. 8e is an FESEM image of Pure MAPbI₃ with the inset showing the corresponding cross-sectional image of perovskite on Si substrate;

FIG. 8f is a FESEM image of 1 wt % PS-MAPbI₃ with the inset showing the corresponding cross-sectional image of perovskite on Si substrate;

FIG. 8g is a graph showing Nyquist plots of impedance (Z) spectra for Au/PS-MAPbI₃ (or MAPbI₃)/Au device measured under (g) dark conditions with inset showing equivalent circuit for analysis and the high frequency component showing charge transport regime;

FIG. 8h is a graph showing Nyquist plots of impedance (Z) spectra for Au/PS-MAPbI₃ (or MAPbI₃)/Au device measured under light illumination (1.0 sun irradiation) conditions with an inset showing the extracted resistance ratio of 1 wt % PS-MAPbI₃ to pure MAPbI₃ device in both dark and light illumination conditions;

FIG. 8i is a FESEM image of a 14 wt % PS-MAPbI₃ film on ZnO/ITO substrate;

FIG. 8j is a FESEM image of a 14 wt % S-MAPbI₃ film on ZnO/ITO substrate;

FIGS. 9a to 9d are FESEM images of a) Plain MAPbI3, b) 1 wt % PS-MAPbI3, c) 3 wt % PS-MAPbI3, and d) 7 wt % PS-MAPbI3 films with respect to a characterization of plain and polystyrene-incorporated perovskite films;

FIGS. 9e to 9g are Raman spectra graphs of plain MAPbI₃, 1 wt %, 3 wt %, and 7 wt % PS-MAPbI films at e) 60-130 cm⁻¹, f) 135-160 cm⁻¹, and g) 180-360 cm⁻¹ wavenumbers showing a shift towards higher wavenumber with PS content;

FIG. 9h is a graph showing X-ray diffraction patterns of plain MAPbI₃, 1 wt %, and 7 wt % PS-MAPbI₃ films.

FIG. 9i is a graph showing Raman spectra of plain MAPbI₃, 1 wt %, 3 wt %, and 7 wt % PS-MAPbI₃ films;

FIG. 10a is a graph showing J_{sc} cycles of plain MAPbI₃, 1 wt %, 3 wt %, and 7 wt % PS-MAPbI₃ devices after 2.5 V/μm poling for 5 min in air under 1.0 sun illumination with respect to device performance, structure, and energy-harvesting capability;

FIG. 10b is a graph showing V_{oc} cycles of plain MAPbI₃, 1 wt %, 3 wt %, and 7 wt % PS-MAPbI₃ devices after 2.5 V/μm poling for 5 min in air under 1.0 sun illumination with respect to device performance, structure, and energy-harvesting capability;

FIG. 10c are graphs showing dark current (and ion migration current) response from the perovskite devices at a constant bias of 3 V;

FIG. 10d is a graph showing Power density dependence on strength of the poling electric fields for 1 wt % PS-MAPbI₃ device without ZnO layer;

FIG. 10e is a graph showing output current and power density as a function of different external resistances for 1 wt % PS-MAPbI₃ device (after 5 V/μm poling) with and without ZnO layer;

FIG. 10f is a Schematic diagram of the self-powered PS-MAPbI₃ pressure sensor where ZnO nanosheets are interfaced with the PS-MAPbI₃ film;

FIG. 10g is a graph showing operational stability and continuous power generation from the 1 wt % PS-MAPbI₃ device (after 5 V/μm poling) interfaced with ZnO nanosheets, examined at a high or maximum power point with a constant resistance of 10 kΩ and a static load of 100 kPa under continuous full-sun illumination in air;

FIG. 10h is a low density FESEM image of electrochemically-deposited ZnO nanosheets;

FIG. 10i is a high density FESEM image of electrochemically-deposited ZnO nanosheets;

FIG. 10j is a graph showing operational stability and continuous power generation data for the 1 wt % PS-MAPbI3 device (after 5 V/μm poling) without ZnO interface, examined at maximum power point with a constant resistance of 20 MΩ under continuous 1.0 sun illumination in air;

FIG. 11a is a graph showing elastic modulus for plain MAPbI3 and PS-MAPbI3 films with varying amount of PS show the stiffness of the films with respect to mechanical properties and pressure-sensing capabilities of monolithic 1 wt % PS-MAPbI₃ pressure sensor;

FIG. 11b is a graph showing that the J_{sc} response is in step with the dynamic and static pressure modulation with respect to mechanical properties and pressure-sensing capabilities of monolithic 1 wt % PS-MAPbI₃ pressure sensor;

FIG. 11c is a graph showing a derivative of the J_{sc} response tracks that of the applied pressure with accuracy with respect to mechanical properties and pressure-sensing capabilities of monolithic 1 wt % PS-MAPbI₃ pressure sensor;

FIG. 11d is a graph showing J_{sc} cycles with various applied pressure stimuli show the consistent response with respect to mechanical properties and pressure-sensing capabilities of monolithic 1 wt % PS-MAPbI₃ pressure sensor;

FIG. 11e is a graph showing a cyclic stability and durability test of the pressure sensor under repetitive high-pressure loading of 333 kPa monitored after 5 V/μm poling for 5 min under 1.0 sun illumination in air with respect to mechanical properties and pressure-sensing capabilities of monolithic 1 wt % PS-MAPbI₃ pressure sensor;

FIG. 11f is a graph showing hardness of plain MAPbI₃, 1 wt %, and 7 wt % PS-MAPbI₃ films;

FIG. 12a is a graph showing a variation of J_{sc} as a function of applied pressure for plain MAPbI₃, 1 wt %, 3 wt %, and 7 wt % PS-MAPbI₃ devices after 1 V/μm poling for 5 min in air under 1.0 sun illumination with respect to pressure sensitivity, linearity, and self-powered operation of the devices;

FIG. 12b is a graph showing relative current of the devices (after 1 V/μm poling) in response to the applied pressure shows the linear response over the broad dynamic range with respect to pressure sensitivity, linearity, and self-powered operation of the devices;

FIG. 12c is a graph showing sensitivity and pressure range of 1 wt % PS-MAPbI3 device (after 5 V/μm poling);

FIG. 12d is a graph showing that J_{sc} response is maintained over 120 h to load cycles of 333 kPa for the 1 wt % PS-MAPbI3 device after initial poling at 5 V/μm for 5 min;

FIG. 12e is a graph showing a comparison of the sensitivity, linear sensing response, and dynamic pressure range of the disclosure with previously reported pressure sensors;

FIG. 12f is a graph showing pressure limits of detection for the 1 wt % PS-MAPbI₃ sensor;

FIG. 12g is a graph showing self-powered operation of a MAPbI₃ pressure sensor;

FIG. 12h is a graph showing self-powered operation of a 3 wt % PS-MAPbI₃ pressure sensor; and

FIG. 12i is a graph showing self-powered operation of a 7 wt % PS-MAPbI₃ pressure sensor.

### DETAILED DESCRIPTION OF THE EMBODIMENTS

The disclosure is directed at a method and system for generating a polymer-perovskite hybrid (PPH). In one embodiment, the hybrid is generated via the combination or mixture of a polymer with a precursor solution of a Lewis acid chemical component and a cation.

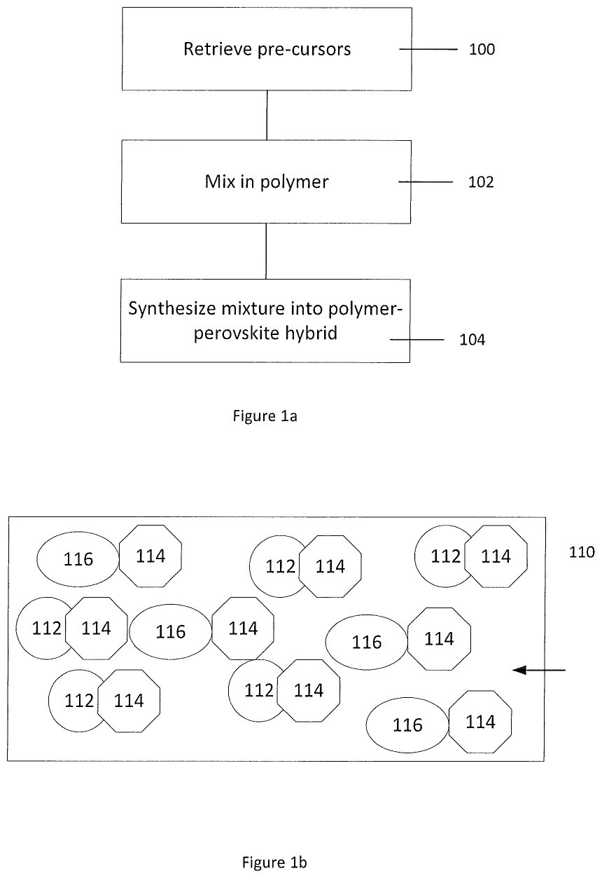

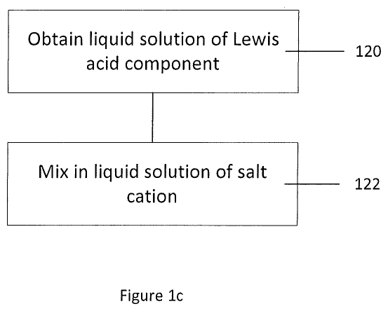

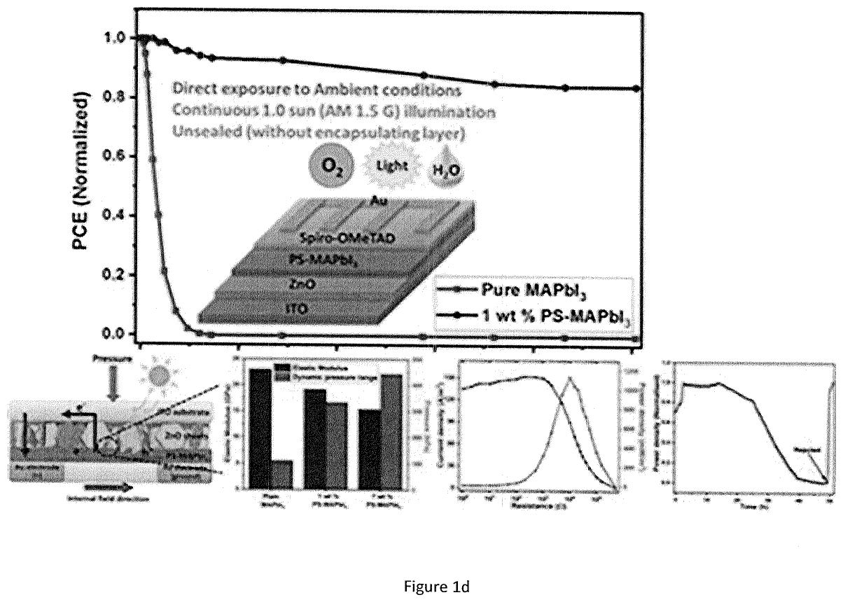

Turning to FIG. 1a, a flowchart outlining a method of generating a polymer-perovskite hybrid is shown. The polymer-perovskite hybrid can then be used in the manufacture of a product such as, but not limited, to a solar cell. The process will be dependent on the resulting final product and/or the application of the final product.

Initially, a set of initial starting components, or precursors, are retrieved (100). In one embodiment, the set of precursors is in a liquid state and includes a Lewis acid chemical component liquid solution and a cation liquid solution. Alternatively, the set of precursors may be retrieved in other states (such as a solid state) and then dissolved into a precursor solution. In one embodiment, the set of initial starting components include a Lewis acid chemical component and a cation component, such as, for example a cation or cations from a salt or more than one salt. In a specific embodiment, the Lewis acid chemical component is lead iodide (PbI₂) and the cation is from Methylammonium Iodide (MAI), with the cation being Methylammonium. In other embodiments, the Lewis acid chemical component may be lead bromide (PbBr₂), lead chloride (PbCl₂), tin chloride (SnCl₂), tin iodiode (SnI₂) or tin bromide (SnBr₂). In other embodiments, the cation or cations component or components may be from Methylammonium bromide, Cesium iodide, Formamidinium iodide or a combination thereof. The set of initial starting components are then mixed with a polymer (or polymer solution) or their oligomers (102) to create or generate the PPH or polymer-perovskite film or a base for the PPH or polymer-perovskite film. In one embodiment, the polymer may be polystyrene chains, however, the polymer may also be, but not limited to, polyvinyl chloride, or polysulfone. When the polymer is mixed in, the Lewis acid chemical component experiences in-situ cross-linking with the polymer while the cation or salt cation interacts with the Tr-electrons of the polymer. The conditions under which the polymer is mixed with the precursor solution is dependent on the different components within the solution or solutions.

For instance, when PbI₂, MAI and polystyrene are used, the PbI₂ and MAI are first dissolved (together or separately) in a solvent or mixture of solvents (such as, but not limited to, a mixture of dimethylformamide (DMF) and Dimethyl sulfoxide (DMSO)). The temperature for mixing for PbI₂ and MAI in the solvent can vary from 10° C. to 100° C. with a mixing time of up to 12 hours. In the current example, the mixing temperature was about 30° C. with a mixing time of about 1 hour. The polystyrene is then, separately, mixed in a solvent or mixture of solvents (such as, but not limited to, a mixture of DMF and DMSO). The temperature for mixing the polystyrene can vary from 10° C. to 120° C. with a mixing time of about 24 hours. In the current example, the mixing temperature was about 70° C. and the mixing time about 3 hours.

Following this, the individual solutions are mixed with each other in predetermined quantities and concentrations to generate the solution for making the polymer-perovskite film. The temperature of mixing for these two solutions can be up to 120° C. In the current example, the mixing temperature was 60° C. The resulting solution or mixture can then be synthesized into a PPH (104). In one example synthesis process, the PPH or PS-MAPbI₃ perovskite films were deposited by a one-step spin-coating process, with antisolvent dripping on to a substrate. The combined precursor and polymer solution was spin-coated at 4000 rpm for 30 s onto a substrate. Diethyl ether was dropped onto the rotating substrate in 10s before the surface changed to be turbid due to the rapid vaporization of DMF. The obtained films were then heated at 65° C. for 2 min and 100° C. for 3 min. Alternatively, the PPH can be made via use of doctor blade, solution casting, spray coating and the like. The PPH can then be used in the manufacture of other products, such as, but not limited to a solar cell.

Turning to FIG. 1b, a schematic diagram of a PPH is shown. The PPH 110 includes Lewis acid chemical components 112 that are cross-linked with a polymer 114 along with cation components 116 that have interacted with the T-electrons of the polymer 114.

Turning to FIG. 1c, an embodiment of retrieving a set of precursors is shown. Initially, a liquid solution of a Lewis acid chemical component is obtained (120). The liquid solution of the Lewis acid chemical component, such as lead iodide, may be previously created or may be generated by dissolving lead iodide in a liquid. A liquid solution of a cation, or salt cation, is then mixed with the liquid solution of the Lewis acid chemical component (122).

In one embodiment of the disclosure, when the Lewis acid chemical component is lead iodide (PbI₂), the salt cation is methylammonium iodide (MAI) and the polymer is polystyrene chains, the resulting PPH can then be synthesized for use in a solar panel such as described below.

In one specific embodiment of the method of FIG. 1a, a precursor solution of PbI₂ and MAI was created (100) by mixing liquid solutions of PbI₂ and MAI. This precursor solution was then mixed with a polymer chain solution (102). In one embodiment, the polymer chain solution can be created by dissolving polystyrene (PS) in DMF and DMSO.

The mixing of the polymer chain solution and the precursor solution results in the Lewis acid characteristics of PbI₂ interacting with the polymer chains in the PS and the MAI to interact with the π-electrons of the PS to assist in producing the PPH mixture which can then be synthesized into a PS-MAPBI₃ film. The interaction between the PbI₂ and the PS results in the formation of a cross linked polymer network within which the polymer-perovskite hybrid which could then be synthesized, such as into solar cells. It was shown that the hydrophobic (organic) PS interacts with PbI₂ (due to its Lewis acid characteristics) and MA+ cations (due to the T electrons of PS), resulting in the stable PS-MAPbI₃ films.

In the following description, use of the term “PS-MAPbI₃” also encompasses the broader term “perovskite-polymer hybrid”.

In one embodiment, as will be discussed below, the integration of a cross-linked polystyrene network with MAPbI₃ films using the Lewis acid characteristic of PbI₂ provides an effective method to synthesize highly stable perovskite films.

### EXPERIMENTAL RESULTS

In this experiment, the composite of the perovskite-polymer (PS-MAPbI₃) hybrid (as a result of synthesis) resulted in a set of highly stable solar cells which operated in ambient conditions (normal air atmosphere, 40-50% relative humidity and continuous 1.0 sun illumination) at 45° C. without any other encapsulating interface for more than 1000 hours and maintained 85% of their performance (more than 90% after 400 hours). In contrast, the efficiency of some current MAPbI₃ solar cells (without any mixing with a polymer) drops to 20% of their initial value after 48 hours.

In the experiment, the PS-MAPbI₃ devices or solar cells also showed stable continuous operation (under ambient air, full-sun (AM 1.5 G) illumination and relative humidity conditions) at a high or maximum power point (MPP) retaining >93% of their initial efficiency after 100 hours. The solar cells developed or synthesized from the perovskite-polymer hybrid also showed improved efficiency and reduced hysteresis compared to current non-polymer perovskite solar cells. It is believe that these improvements were due to at least one of the following advantages: reduced ion migration and charge recombination, better mobility and carrier life time, larger grain size and/or lower dark current in the perovskite-polymer hybrid, or films generated by the method of the disclosure. The interaction of the PS with the constituting anions and the cations in the perovskite crystal was observed in characterization results and provided an improved or enhanced stability, due to its in-situ crosslinking with PbI₂.

An advantage of the current disclosure is that when a low cost polymer additive is used in the fabrication process or method of the polymer-perovskite hybrid (as disclosed in FIG. 1a), this results in a cost effective method for commercializing thin-film solar cells based on hybrid organolead halide perovskites. It was also shown in this experiment that the solar cell efficiency was improved from 15.5% (with some current pure MAPbI₃ solar devices) to 16.8% for the 1 wt % PS-MAPbI₃ film solar cells. It was determined that the extent of polystyrene cross-linking (controlled by its fraction in the casting solution) directly affects the performance of the perovskite films and their stability. With a higher degree of cross-linking (between the polymer and the Lewis acid chemical component), the stability of the film increases. This is due to the fact that its performance does not follow a monotonic trend with an observed high or maximum at 1 wt % PS concentration. It was also noted that the use of a styrene (S) monomer provided some stability but not as much as when a polymer was used due to the cross-linking with the Lewis acid chemical component.

It was shown that the PS coupled MAPbI₃ film (or perovskite-polymer hybrid) continuously harvests ambient light energy on poling and also functions as a pressure sensor. By varying the polymer content such as up to about 20% by WT of the precursor solution, the mechanical response of the polymer-perovskite films can be tuned with their modulus varying in the range of ˜23 GPa to ˜15 GPa. Further due to the restriction of ion-migration in the PS-MAPbI₃ films, these films have stable poling effects and can be poled at high voltages leading to continuous and stable power generation of 1.1 W/m² on illumination. This enables a way to observe stable and significant spin-orbit coupling effects in these films.

Applied as a pressure sensor, the PS-MAPbI₃ films have a linear response with high sensitivity (up to 20 kPa⁻¹) over a wide and tunable operating range (up to 450 kPa) and a low or minimum detection limit of 4 Pa, in a single structure and can be powered by just light illumination. This combination of characteristics is beneficial for monitoring diverse stimuli ranging from a low pressure (<1 kPa) to a high pressure range (>100 kPa). Moreover, as the pressure sensor operates in a linear regime, more accurate information can be obtained from its output without the need of any additional signal processor.

This may provide the benefit of meeting the increasing demand for device miniaturization and low power consumption. Although several nano-micro structuring approaches have been adopted in order to attain high sensitivity, achieving it in combination with wide operating range and linear response still remains a challenge, limiting their practical use. The integration of PS with MAPbI₃ addresses this challenge in a simple monolithic pressure sensor by combining organic polymer with organolead halide perovskites.

As discussed above, the hydrophobic (organic) PS interacts with PbI₂ (due to its Lewis acid characteristics) and MA+ cations (due to the Tr electrons of PS), resulting in stable PS-MAPbI₃ films or perovskite-polymer hybrids. Poling generates an internal polarization in the films and on illumination the generated charge carriers are separated and collected by electrodes enabling the PPH or polymer-perovskite films act as energy harvesters using ambient light. In experiments, it was determined that a high or maximum power density of 1.1 W/m² is harvested on illumination with 1.0 sun for devices poled for 5 min. They continuously generate power for more than 24 hours and can then be repoled to regain their energy harvesting efficiency. The semiconducting nature of perovskite combined with its polarization effects and integration with PS presents a method and apparatus to complement the capabilities of triboelectric generators for use in a variety of energy harvesting devices for broader application. This capability can also be integrated with the sensing of stimuli as the active layer in the device is a semiconducting perovskite, as is demonstrated by the reported pressure sensor.

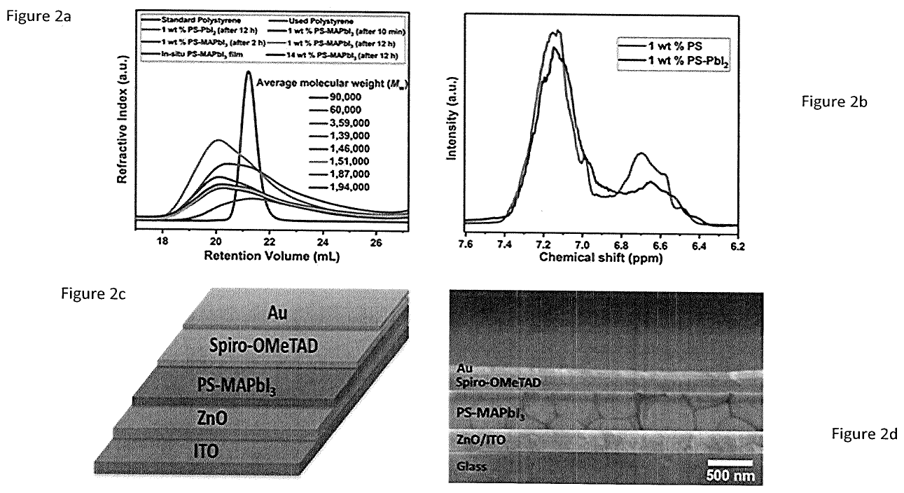

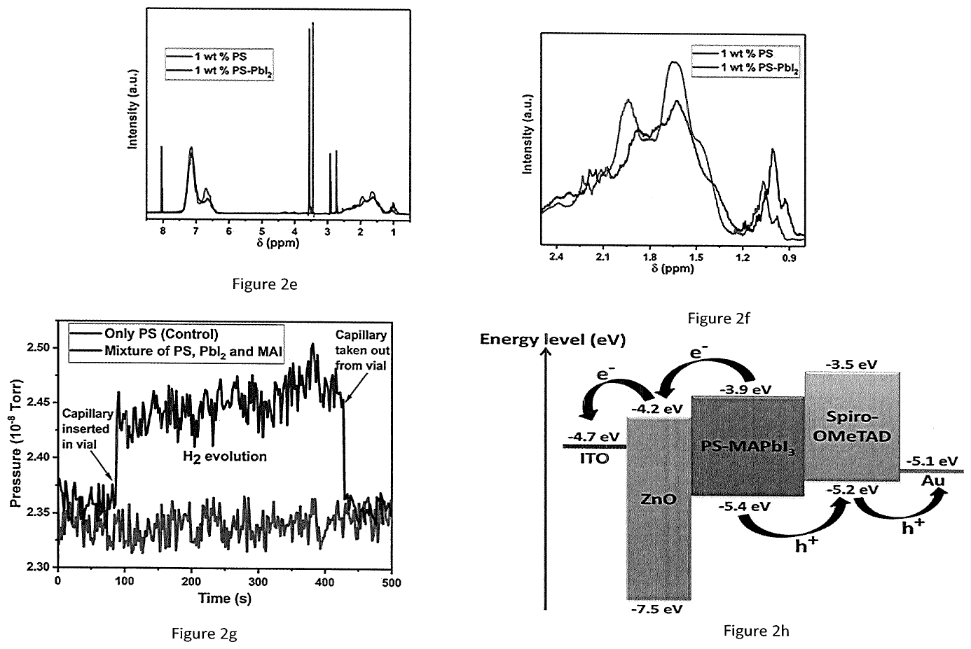

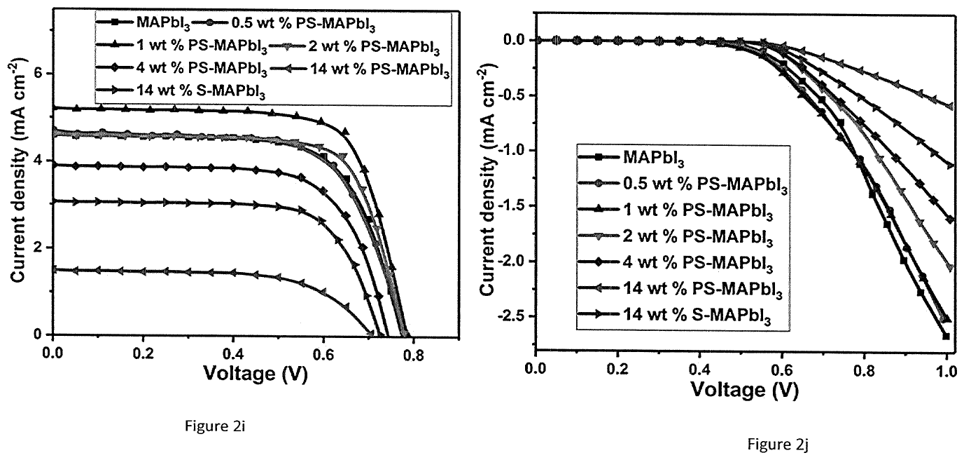

While PbI₂ has been discussed as the Lewis acid chemical component, other Lewis acids such as, but not limited to, AlCl₃ (and other Aluminum halides), lead bromide (PbBr₂) or lead chloride (PbCl₂) are known to interact with PS and one of the reaction pathways leads to the formation of carbonium ions that subsequently cause cross-linking of the PS chains. The cross-linking of the PS on mixing with PbI₂ was confirmed by the Gel permeation chromatography (GPC) results, as shown in FIG. 2a.

Furthermore, the standard (for calibration) and the used plain PS (control samples) have a molecular weight (Mw) of 90,000 and 60,000, respectively. A 1% (by weight) PS solution in PbI₂ (62% by weight) characterized after 12 hours shows a Mw of 359,000 (an increase of ˜6 times as compared to plain PS), which reveals the cross-linking of the polymer. The Mw increases with reaction time and also with the wt % of PS in the solution (inset of FIG. 2a). The PS from casted PS-MAPbI₃ films shows a Mw of 187,000 which confirms the cross linking of PS within MAPbI₃ film. Nuclear magnetic resonance spectra (NMR, H1) shows a shift in the PS peaks due to interaction with PbI₂ and formation of intermediate cation complex that subsequently losses hydrogen and leads to the formation of carbonium ions (FIGS. 2b, 2e and 2f).

As shown in FIGS. 2e and 2f, the sharp NMR peaks for 1 wt % PS solution at 2.737, 2.899, and 8.018 ppm is attributed to DMF. The intense peak at 3.557 ppm and 3.452 ppm is ascribed to the presence of water (or moisture) in DMF and DMSO. The broad peaks at δ=6.698 and 7.125 ppm for 1 wt % PS solution is attributed to the presence of polystyrene. The peaks below 2.5 ppm are due to aliphatic regions of PS. The observed upshift for PS peaks in 1 wt % PS—PbI2 solution is due to the interaction of PS and PbI₂ intermediates which leads to the formation of carbonium ions.

In the presence of moisture (as seen in NMR spectra), the Lewis acid (PbI₂) hydrolyzes and results in formation of hydrogen iodide (HI). The PbI₂ interact with PS in the presence of HI which leads to the formation of cation complex on the main chain, i.e. polymeric cations complex with PbI₃—. This complex upshifts the observed NMR resonances for both the aromatic and aliphatic regions of PS. The carbonium ions then react with other polystyrene chains at the site of the tertiary carbon atom leading to the cross-linking of the polymer chains. Further, it was observed that the evolution of hydrogen gas (FIG. 2g) from the PS and perovskite reaction mixture which supports the understanding of the proposed cross-linking mechanism of PS due to the Lewis acid nature of PbI₂.

This direct interaction typically leads to slower crystallization kinetics in the perovskite films and improves the quality of the crystals. Direct interactions between inorganic crystals and organic moieties are well understood in natural systems where they are used to develop composite materials such as bones and shells that have distinct properties compared to their pure inorganic counterparts.

The effect of the cross-linking on the performance of PS-MAPbI₃ solar cells, its stability and structure was then analyzed and compared to plain MAPbI₃. The device configuration of the perovskite solar cells (PSCs) is shown in FIG. 2c, with a representative cross-sectional field emission scanning electron microscopy (FESEM) image illustrated in FIG. 2d. A ZnO film deposited on indium tin oxide (ITO) glass substrate as the electron transport layer (ETL), the PS-MAPbI₃ (or pure MAPbI₃) film was grown as the active light absorbing layer by a facile one-step solution casting method, Spiro-OMeTAD as the hole transport layer (HTL), and gold (Au) as the top electrode. The energy level diagram of the device is presented in FIG. 2h.

The performance of perovskite solar cells with varying amounts of PS content (0, 0.5, 1, 2, 4, and 14 wt %) and without HTL were measured under illumination (FIG. 2i) and in dark (FIG. 2j), with the detailed device parameters listed in Table 1 which is a summary of device performance for pure MAPbI₃, PS-MAPbI₃ (different concentrations), and S-MAPbI₃ solar cells without HTL. A batch of 10 individual devices were fabricated and measured for each perovskite layer to gain more reliable statistical information.

TABLE 1

| Perovskite layer | J_{sc} (mA cm⁻²) | V_{oc} (V) | FF | PCE (%) |
|---|---|---|---|---|
| Pure MAPbI₃ | 4.61 ± 0.06 | 0.775 ± 0.01 | 0.696 ± 0.014 | 2.49 ± 0.13 |
| 0.5 wt % PS-MAPbI₃ | 4.70 ± 0.03 | 0.776 ± 0.02 | 0.694 ± 0.010 | 2.53 ± 0.14 |
| 1 wt % PS-MAPbI₃ | 5.21 ± 0.04 | 0.784 ± 0.01 | 0.745 ± 0.012 | 3.04 ± 0.10 |
| 2 wt % PS-MAPbI₃ | 4.61 ± 0.10 | 0.779 ± 0.01 | 0.741 ± 0.021 | 2.66 ± 0.15 |
| 4 wt % PS-MAPbI₃ | 3.90 ± 0.06 | 0.740 ± 0.02 | 0.695 ± 0.015 | 2.00 ± 0.12 |
| 14 wt % PS-MAPbI₃ | 1.50 ± 0.02 | 0.710 ± 0.01 | 0.642 ± 0.010 | 0.68 ± 0.10 |
| 14 wt % S-MAPbI₃ | 3.07 ± 0.07 | 0.725 ± 0.01 | 0.706 ± 0.018 | 1.57 ± 0.09 |

It was observed that 1 wt % PS-MAPbI₃ device without HTL exhibits the best performance, with a PCE of 3.04%, short-circuit current density (J_{sc}), open circuit voltage (V_{oc}), and fill factor (FF) of 5.21 mA cm-2, 0.784 V, and 0.745, respectively. In comparison, the pure MAPbI₃ device without HTL showed a PCE of 2.49% with a J_{sc} of 4.61 mA cm⁻², Vₐ of 0.775 V, and FF of 0.696. Increasing the PS content further decreases the device performance, as seen for 4 wt % PS-MAPbI₃ that has a PCE of 2.00% and for 14 wt % PS-MAPbI₃ the PCE reduces to just 0.68%. The J-V curves measured in the dark (FIG. 2j) show that the current density decreases with increasing PS content, revealing that the electrically insulating nature of PS reduces the dark current in these devices. The performance of the solar cells with a HTL also follows a similar trend.

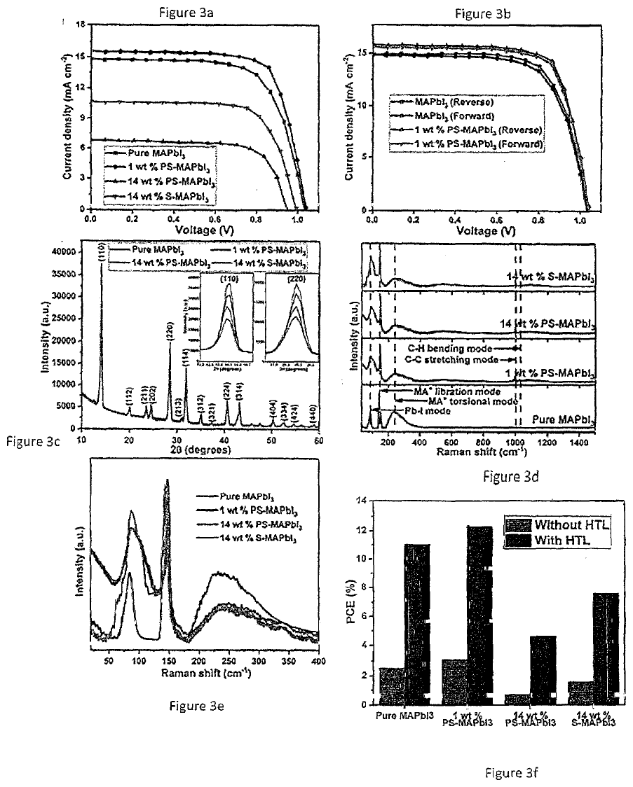

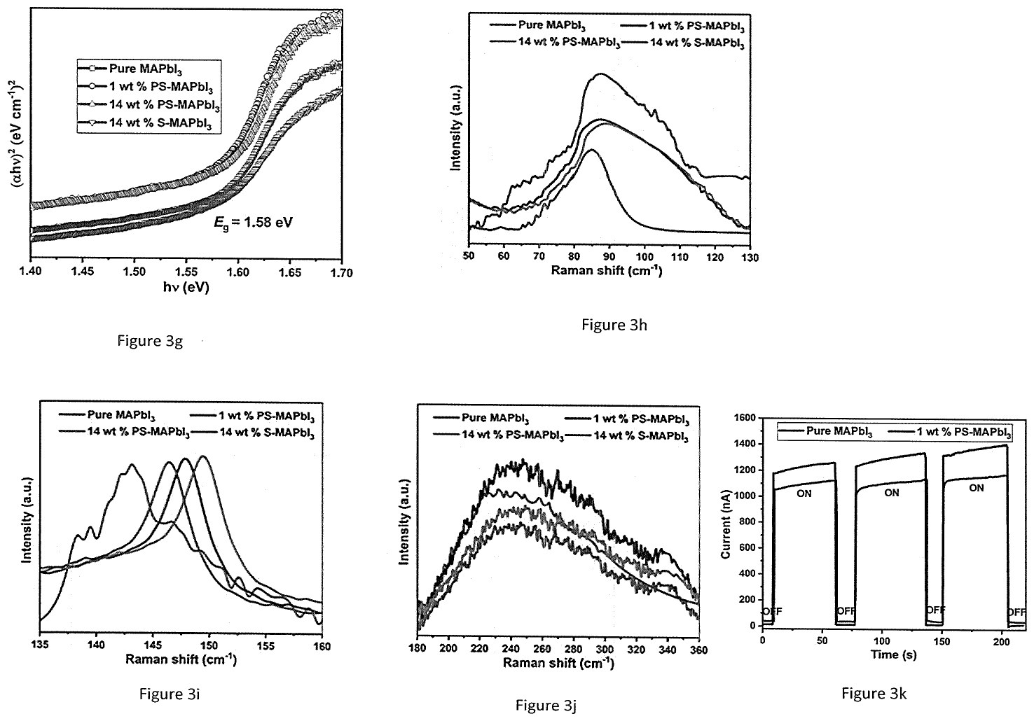

FIG. 3a shows the J-V characteristics of the pure MAPbI₃, PS-MAPbI₃ (1 and 14 wt %), and 14 wt % S-MAPbI₃ devices with HTL, and the corresponding device parameters are summarized in Table 2. Again, a batch of 10 individual devices were fabricated and measured for each perovskite layer to gain more reliable statistical information.

TABLE 2

| Perovskite layer | J_{sc} (mA cm⁻²) | V_{oc} (V) | FF | PCE (%) |
|---|---|---|---|---|
| Pure MAPbI₃ | 14.88 ± 1.23 | 1.033 ± 0.05 | 0.717 ± 0.015 | 11.02 ± 1.77 |
| 1 wt % PS-MAPbI₃ | 15.80 ± 1.18 | 1.044 ± 0.08 | 0.744 ± 0.011 | 12.27 ± 1.83 |
| 14 wt % PS-MAPbI₃ | 6.79 ± 0.25 | 0.951 ± 0.02 | 0.712 ± 0.019 | 4.60 ± 0.21 |
| 14 wt % S-MAPbI₃ | 10.66 ± 0.13 | 0.995 ± 0.01 | 0.714 ± 0.013 | 7.57 ± 0.15 |

The 1 wt % PS-MAPbI₃ device shows the highest PCE of 12.27%, with a V_{oc}, of 1.044 V, J_{sc} of 15.80 mA cm-2, and FF of 0.744. In contrast, the plain MAPbI₃ device showed a PCE of 11.02% with a V. of 1.033 V, J_{sc} of 14.88 mA cm-2, and FF of 0.717, which is comparable with the previous reports. Note the performances reported here are for typical devices, the best devices have a PCE of ˜15.5% for pure MAPbI₃ and 16.8% for 1 wt % PS-MAPbI₃. Further, the PCE of different devices with and without HTL were compared. The results are displayed as a bar graph in FIG. 3f. The forward and reverse J-V scans of the 1 wt % PS films show a hysteresis index of 0.017 compared to 0.032 for pure MAPbI₃ FIG. 3b. The detailed parameters for the hysteresis analysis are listed in Table 3.

TABLE 3

| | | J_{sc} | | | | |
|---|---|---|---|---|---|---|
| Perovskite | Scanning | (mA | V_{oc} | | PCE | Hysteresis |
| layer | direction | cm⁻²) | (V) | FF | (%) | index |
| Pure MAPbI₃ | Reverse | 14.88 | 1.033 | 0.717 | 11.02 | 0.032 |
| | Forward | 14.79 | 1.032 | 0.699 | 10.67 | |
| 1 wt % PS- | Reverse | 15.80 | 1.044 | 0.744 | 12.27 | 0.017 |
| MAPbI₃ | Forward | 15.58 | 1.043 | 0.742 | 12.06 | |

The results show that the hysteresis challenge is considerably alleviated in the presence of cross-inked PS. This is attributed to the reduction in ion migration in the PS-MAPbI₃ active layer.

The influence of PS cross-linking on the perovskite crystal structure was investigated by X-ray diffraction (XRD), UV-Vis absorption spectra, and Raman spectroscopy. XRD patterns (FIG. 3c) showed no change in the crystalline phase of perovskite with or without PS and S, but displayed the difference in the diffraction intensities and sharpness (see inset of FIG. 3c). The diffraction intensity of 1 and 14 wt % PS-MAPbI₃ films is higher than that of the pure MAPbI₃ and 14 wt % S-MAPbI₃ films, suggesting a higher crystallinity in the presence of PS. Further, it was observed that the crystallinity improves on increasing PS content from 1 to 14 wt % and is suppressed with the styrene monomer. These results indicate that the PS incorporation into MAPbI₃ has a significant effect on the crystallization behavior. The energy band gap (shown in FIG. 3g) calculated using absorption spectra showed no obvious change with and without PS and S. From the Raman spectra as shown in FIG. 3d, the sharp characteristic bands at 85 and 143 cm⁻¹ can be attributed to the Pb—I and MA+ libration modes, respectively. The broad band with maxima around 240 cm⁻¹ assigned to the torsional mode of MA+ in the MAPbI₃. A shift in the Pb—I, MA+ libration, and MA+ torsional modes from 85 to 89 cm-1, 143 to 149 cm⁻¹ and 240 to 247 cm⁻¹, respectively with the increase in the polystyrene concentration as shown in FIGS. 3e, 3h, 3i and 3j. These Raman shift towards higher wavenumber reflects the interaction of the PS with MAPbI₃. Further, the signal at 998 cm⁻¹ ascribed to C—C aromatic (stretching mode), and the band at 1030 cm⁻¹ which corresponds to C—H aromatic (bending mode) are present both in PS-MAPbI₃ (and S-MAPbI₃) films which represents the incorporation of PS (or S) into MAPbI₃.

The photocurrent was also measured for a vertical device configuration as shown in FIG. 3k to confirm that the cross-linked PS is included in the bulk MAPbI₃. The photocurrent for 1 wt % PS-MAPbI₃ is higher as compared to the pure MAPbI₃ which reveals the successful incorporation of PS matrix into the perovskite film and not just as an insulting layer on the surface. Based on these results, it is understood that PS chains are incorporated at the grain boundaries of the perovskite crystals. In the graph, OFF refers to current measured under dark and ON refers to current measured under light (1.0 sun) illumination.

Despite exhibiting high photovoltaic efficiency, one major concern of non-polymer perovskite solar cells and devices is their long-term stability. Therefore, the stability of the devices and films synthesized using the PPH of the current disclosure without any encapsulation layer was monitored in ambient air at 45° C., under continuous 1.0 sun illumination (including UV light) and moisture (relative humidity of 40-50%).

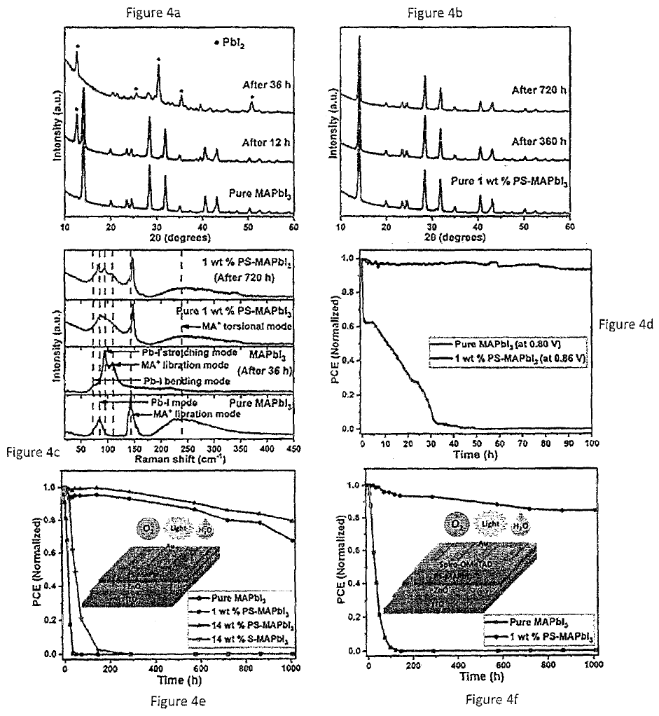

As observed in XRD pattern of pure MAPbI₃ (FIG. 4a), the PbI₂ peak at 12.65° starts appearing along with the typical MAPbI₃ peaks after 12 hours of continuous exposure and the film completely turns into PbI₂ after just 36 hours. Whereas, the diffraction patterns of 1 wt % PS-MAPbI₃ film (FIG. 4b) reveal that the MAPbI₃ crystal structure remains stable (no degradation) even after 720 hours (30 days). The Raman spectra of pure MAPbI₃ and 1 wt % PS-MAPbI₃ films were compared (FIG. 4c) to gain more insight into the degradation. After 36 hours of exposure for the pure MAPbI₃ film, the MA+ torsional mode disappeared and two new bands at 73 and 95 cm⁻¹ were observed which is due to the degradation of MAPbI₃ into PbI₂. While for the 1 wt % PS-MAPbI₃ film, MA+ libration and torsional modes remain intact after 30 days. This signifies the effect of cross-linking of PS on increasing the stability of the PS-MAPbI₃ films. Following this, the stability of pure MAPbI₃ (reference), and 1 wt % PS-MAPbI₃ (optimized) solar cells with and without HTL were investigated by exposing them simultaneously to three factors of moisture, oxygen and 1.0 sun illumination. The stability data was recorded for the devices with the best efficiency (16.8% for 1 wt % PS-MAPbI₃). In all cases, cross-linking of PS into the devices presents further substantial improvement in the stability of PSCs. FIG. 4d illustrates the PCEs for the devices with HTL recorded as a function of time under a constant bias voltage at the MPP (0.80 V for the MAPbI₃ and 0.86 V for the 1 wt % PS-MAPbI₃ device), and under continuous ambient air (relative humidity of 40-50%) and 1-sun illumination at 45° C. The 1 wt % PS-MAPbI₃ devices maintain more than 93% of their initial PCE after 100 hours, whereas under the same conditions the PCE of pure MAPbI₃ dropped to zero within 30 hours. The long-term stability of the PSCs without HTL (FIG. 4e) and with HTL (FIG. 4f) was also examined by exposing the devices to ambient air, moisture (40-50% relative humidity) and full sun illumination (including UV light) at 45° C.

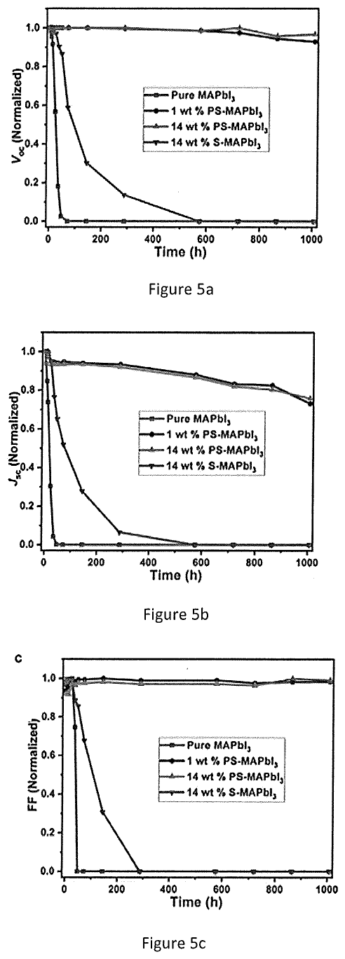

FIG. 4e shows that the PCE for 1 and 14 wt % PS-MAPbI₃ PSCs without HTL retained 68% and 80% of their initial values after 42 days, respectively. In contrast, the PCEs for pure MAPbI₃ and 14 wt % S-MAPbI3 devices dropped to 20% of their initial values after 24 hours and 72 hours, respectively. The other normalized solar cell figures of merit (V_{oc}, J_{sc}, and FF) without and with HTL are shown in FIGS. 4 and 5, respectively.

As can be seen in FIGS. 5a to 5c, 1 and 14 wt % PS-MAPbI₃ devices maintain more than 92% of their initial V_{oc} after 1008 hours, whereas under the same conditions the measured V_{oc} decreased to zero in pure MAPbI₃ (after 48 hours) and 14 wt % S-MAPbI₃ (after 300 h) solar cells. The J_{sc} of 1 and 14 wt % PS-MAPbI₃ PSCs maintained more than 70% of their initial values after 42 days. While the measured J_{sc} decreased to zero for pure MAPbI₃ (after 48 hours) and 14 wt % S-MAPbI3 (after 300 hours) solar cells. The FF for 1 and 14 wt % PS-MAPbI₃ devices retain more than 98% of their initial value, while for pure MAPbI₃ and 14 wt % S-MAPbI₃ devices the FF gradually decreased to zero within 48 hours and 288 hours of continuous light and moisture exposure at 45° C., respectively.

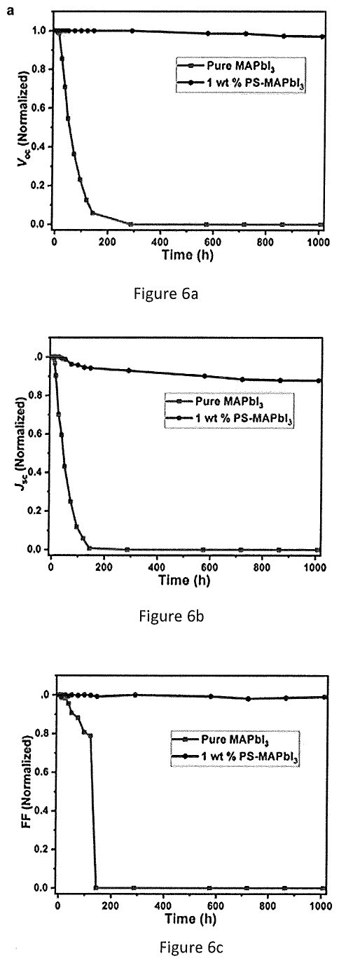

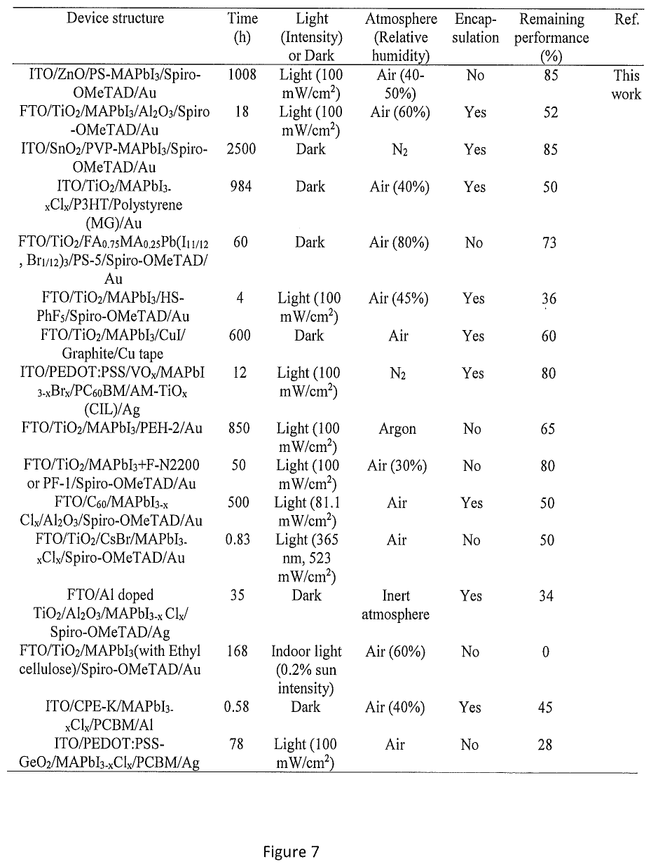

As seen in FIGS. 6a to 6c, the 1 wt % PS-MAPbI₃ PSCs retain at least 97% of their highest V=after 1008 hours, whereas the V_{oc}, for pure MAPbI₃ PSCs decreased to zero after 144 hours under continuous one sun illumination, and ambient air at 45° C. with a relative humidity of 40-50%. After 42 days, the J_{sc}, of 1 wt % PS-MAPbI₃ PSCs maintained more than 87% of their initial values. In contrast, the measured J_{sc} for pure MAPbI₃ solar cells decreased to zero after 120 hours (5 days). The 1 wt % PS-MAPbI₃ devices maintain 99% of their initial FF, whereas the FF gradually decreased to zero for pure MAPbI₃ devices after 120 hours under the combined effect of continuous light, air and moisture.

FIG. 4f illustrates that the 1 wt % PS-MAPbI₃ PSCs with HTL maintained 85% of their peak PCE after exposing continuously in full sun illumination, and ambient air at 45° C. with a relative humidity of 40-50% for 42 days. While the pure MAPbI₃ PSCs retained only 20% of their initial PCE after 48 hours. This result confirms that the perovskite film with PS is more stable at harsh environmental conditions. It is believed that the improved device stability is due to the direct interaction between the MAPbI₃ grain boundaries and the cross-linked PS, which will block the ion migration and also reduce or prevent the penetration of oxygen and water (moisture) into the perovskite layer, and hence impede the decomposition of MAPbI₃ under light. The long-term stability comparison of PS-MAPbI₃ solar cells with several other device configurations under different conditions is shown in the table of FIG. 7. It should be noted that the device synthesized from the PPH disclosed above without any encapsulation shows the superior stability.

To gain an understanding of the greater stability combined with higher performance in the PS based perovskite films compared to plain films, ion migration and dark currents, film structure, time-resolved photoluminescence (TRPL), trap-state density and carrier mobility, and their electrochemical impedance spectra were analyzed. The current-response under dark and light illumination from a planar lateral device of configuration Au/PS-MAPbI₃ (or MAPbI₃)/Au at a constant bias of 5 V was measured. As shown in FIG. 8a under dark, the initial current at t=0 s for PS-MAPbI₃ (1.18 nA) is more than an order of magnitude less compared to MAPbI₃ (15.3 nA) which is attributed to the presence of polystyrene (insulating material) in the perovskite film. After 850 s, the current for PS-MAPbI₃ maintained 52% of its initial value, whereas the current for MAPbI₃ dropped to 91% of its initial value which reveals that the ion migration effects are significantly reduced in PS-MAPbI₃ device. Under illumination (FIG. 8b), it is clearly observed that the PS-MAPbI₃ device shows a higher photo-current generation (760 nA) with no observable decay, whereas the MAPbI₃ device shows a lower photo-current (500 nA) and it decays by 16% within 28 s due to the back diffusion of ions and recombination of charge carriers. These results confirm that the cross-linking of polystyrene into the perovskite material suppresses the ion migration effects and at the same time also enhances the efficiency of photo-carrier generation. To analyze the charge carrier recombination and emission properties, time-resolved photoluminescence (TRPL) and steady-state PL were conducted. As displayed in the inset of FIG. 8c, the emission wavelength for both the films was obtained at 775 nm. However, the PL emission for 1 wt % PS-MAPbI₃ film is higher as compared to the pure MAPbI₃ film which can be attributed to the reduced surface-trap states and defects in the PS incorporated perovskite film. FIG. 8c presents the PL decay for perovskite films with and without PS. The PL decay curves were fitted to a bi-exponential rate law (details in Supporting Information). The 1 wt % PS-MAPbI₃ film exhibits fast and slow phase lifetimes of T1=22.9 ns and T2=264.6 ns, while the pure MAPbI₃ film shows lifetimes of T1=17.9 ns and T2=142.5 ns. This increase in the lifetimes for PS-MAPbI₃ film indicates a lower defect concentration, and hence improves the device performance and stability. Further, the trap density and carrier mobility from the dark I-V characteristics using the standard space charge limited current (SCLC) method were calculated. As shown in FIG. 8d, the I-V traces have the Mott-Gurney's power law dependence (I∝Vn), n=1 is the ohmic region, n>3 is the trap-filled limit (TFL) regime, and n=2 is the trap-free SCLC regime. The VTFL, trap density (ntrap), and carrier mobility for pure MAPbI₃ film were measured to be 0.12 V, 2.36×1015 cm⁻³, and 0.21 cm² V⁻¹ s⁻¹, respectively. In contrast, the 1 wt % PS-MAPbI₃ film resulted in the reduction of VTFL (0.07 V) and trap density (1.37×1015 cm-3); and improvement in the carrier mobility to 0.41 cm² V⁻¹ s⁻¹. This leads to superior device performance and improved stability for PS-MAPbI₃ film. The structure of these films is analyzed by FESEM (FIGS. 8e, 8f and 8i). It was observed that the pure MAPbI₃ and 1 wt % PS-MAPbI₃ form compact and uniform multi-crystalline films. The average grain size of pure MAPbI₃ is 240 nm, while 1 wt % PS-MAPbI₃ has larger crystal grains with an average size of 450 nm. The corresponding cross-sectional images (inset of FIGS. 8e and 8f) show that the grain size of the perovskite film increases with the incorporation of PS (1 wt %) into MAPbI3. On increasing the PS concentration to 14 wt %, the grains aggregated and form large-sized dendritic bundle-like crystals with poor film coverage (FIG. 8i). The 14 wt % S-MAPbI₃ film produces smaller grains with an average size of 65 nm with several pinholes (FIG. 8j). FIGS. 8g and 8h illustrate the typical impedance spectra for the MAPbI₃ and 1 wt % PS-MAPbI₃ devices measured by applying 20 mV AC voltage in dark and light illumination respectively. The equivalent circuit can be simplified to the circuit model shown in the inset of FIG. 8g including a series or electrode resistance of the device (R1), charge transfer resistance (R2), ion diffusion resistance (R3), and charge carrier recombination resistance (R4). The fitted parameters values for MAPbI3 and PS-MAPbI3 devices and their relative errors are listed in Table 4 which shows Impedance spectra parameters values (with goodness of fit, X2) for MAPbI₃ and PS-MAPbI₃ devices measured under dark and light illumination.

TABLE 4

| Dark | | | | | | Light | | | |
|---|---|---|---|---|---|---|---|---|---|
| Parameters | | MAPbI₃ | | 1 wt % PS-MAPbI₃ | | MAPbI₃ | | 1 wt % PS-MAPbI₃ | |
| R₁ | (MΩ) | 0.11 | (±0.00358) | 0.12 | (±0.003025) | 0.0116 | (±0.00037) | 0.0127 | (±0.000463) |
| C₂ | (pF) | 9.35 | (±1.83 × 10⁻⁶) | 0.5 | (±0.93 × 10⁻⁶) | 408 | (±6.50 × 10⁻⁴) | 441 | (±1.40 × 10⁻³) |
| R₂ | (MΩ) | 4.78 | (±0.6451) | 203 | (±0.5086) | 0.57 | (±0.0976) | 0.42 | (±0.022) |
| C₃ | (pF) | 14.07 | (±1.91 × 10⁻⁶) | 8.82 | (±1.57 × 10⁻⁶) | 144 | (±0.55 × 10⁻⁴) | 127 | (±2.13 × 10⁻⁴) |
| R₃ | (MΩ) | 3.01 | (±0.4985) | 6.20 | (±0.27) | 0.33 | (±0.0542) | 0.62 | (±0.058) |
| C₄ | (nF) | 0.538 | (±2.13 × 10⁻⁹) | 0.192 | (±5.12 × 10⁻¹⁰) | 1.29 | (±1.13 × 10⁻⁶) | 0.354 | (±3.48 × 10⁻⁷) |
| R₄ | (MΩ) | 168.45 | (±0.6412) | 533.74 | (±0.2958) | 0.46 | (±0.0957) | 0.98 | (±0.017) |

| | | | | |
|---|---|---|---|---|
| X² | 0.0056 | 0.0014 | 0.0058 | 0.0074 |

The resistance ratio of 1 wt % PS-MAPbI₃ to pure MAPbI₃ device calculated using the equivalent circuit model under dark and light illumination are listed in table (see inset of FIG. 8h). The R1 ratio of the pure MAPbI₃ and 1 wt % PS-MAPbI₃ devices is almost similar due to an identical electrode of device. The R2 value in dark for 1 wt % PS-MAPbI₃ is 42 times higher as compared to pure MAPbI₃, whereas in light the R2 value for 1 wt % PS-MAPbI₃ is 0.73 times lower than pure MAPbI₃. This is ascribed to the lower dark current and higher photocurrent for 1 wt % PS-MAPbI₃ device. The R3 value for 1 wt % PS-MAPbI₃ is twice as compared to pure MAPbI₃ under both conditions, and can be attributed to lower ion migration effect in 1 wt % PS-MAPbI₃ device. For 1 wt % PS-MAPbI₃, the R4 value is thrice (in dark) and twice (in light) than pure MAPbI₃, which is due to fewer defect-assisted traps, indicating more efficient charge transfer and effective suppression of the charge recombination in 1 wt % PS-MAPbI₃ device. The combined results show that 1 wt % PS-MAPbI₃ devices have the best performance and stability resulting from the combination of higher photo-carrier generation due to a higher mobility and lifetime due to larger crystal grain size and passivation of defects by direct interaction between PS chains and perovskite crystals, coupled with significantly reduced dark current, charge recombination and ion migration effects due to the insulating nature of the cross linked PS matrix that is incorporated into the polymer-perovskite film.

To study the mechanical properties, poling effects and ability to function as tactile sensors, the plain MAPbI₃ and PS-MAPbI₃ films were made by the standard solution casting and solvent annealing methods. For the PS-MAPbI₃ films, the wt % of PS was controlled in the precursor solution and the time for crosslinking is kept constant for all the films. The field emission scanning electron microscopy (FESEM) images of the plain MAPbI₃ and 1 wt %, 3 wt %, and 7 wt % PS-MAPbI₃ films are shown in FIGS. 9a to 9d, and uniform crystalline films are observed in all cases. The corresponding X-ray diffraction and Raman spectra are presented in FIGS. 9h and 9i. Specifically, a Raman shift was observed in the Pb—I mode from 84 cm⁻¹ in plain MAPbI₃ films to 92 cm⁻¹ in 7 wt % PS-MAPbI₃ films, which is attributed to the interaction between PS and PbI2 (FIG. 8e). It was also observed that the MA+ libration mode shifts from 143 cm⁻¹ in plain MAPbI₃ films to progressively higher energy as the PS content is increased, reaching 150 cm⁻¹ for 7 wt % PS-MAPbI₃ films (FIG. 8f). Similarly, the MA+ torsional mode also shifts from ˜247 cm⁻¹ in plain MAPbI₃ films to ˜258 cm⁻¹ in 7 wt % PS-MAPbI₃ films (FIG. 8g). The MA+ libration and torsional shifts signify the interaction between the π-electrons of PS and the MA+ cations, which directly impacts its local motion in the perovskite lattice. The cross-linking of the PS chains due to Lewis acid nature of PbI₂ is confirmed by gel permeation chromatography as outlined in Table 5 which shows weight average molecular weight (Mw) of different samples dissolved in Tetrahydrofuran (THF).

TABLE 5

| Samples | M_{w} |
|---|---|
| Used Polystyrene (PS) | 60,000 |
| 1 wt % PS-MAPbI₃ (after 10 min) | 1,39,000 |
| 1 wt % PS-MAPbI₃ (after 2 h) | 1,46,000 |
| 1 wt % PS-MAPbI₃ (after 12 h) | 1,51,000 |

The short-circuit current density (J_{sc}) and open-circuit voltage (V_{oc}) characteristics of plain MAPbI₃ and PS-MAPbI₃ films with varying amount of PS in the precursor solution after poling at electric fields of 2.5 V/μm (applied for 5 min) are shown in FIGS. 10a and 10b, respectively. It was observed that all films show J_{sc} and V_{oc} generation, however, the 1 wt % PS films have the highest response. These films were then studied in greater detail. Further, ion migration in the films was recorded by their current response in dark to a constant bias; the observed decay in current is a direct measure of the extent of ion migration. As seen in FIG. 10c, the presence of PS significantly reduces the ion migration current, which allows these PS films to be poled at high field strengths compared to the plain MAPbI₃ films. The 1 wt % PS-MAPbI₃ films show a monotonous increase in power density with poling fields (FIG. 10d), consistent with the expectation that higher fields will increase internal polarization. A high or maximum power density of the 1 wt % PS-MAPbI₃ films is recorded as 215 mW/m² using an external load resistor as shown in FIG. 10e, after poling at 5 V/μm. Perovskite films are good hole conductors but their electron conductivity is limited, hence to further improve the performance of energy harvesting a top layer of ZnO nanosheets (morphology shown in FIGS. 10h and 10i) is interfaced with the PS-MAPbI₃ films (schematic in FIG. 10f, with a static load of 100 kPa) for more efficient extraction of electrons. As a result, the power density increases to 1.1 W/m² (FIG. 10e). Continuous and stable power generation is observed in these films (with ZnO layer) for more than 24 hours (FIG. 10g), subsequently, on repoling the efficiency is recovered. The loss is hence attributed to the depolarization of the films and not to any structural degradation. 1 wt % PS-MAPbI₃ films without the ZnO interface also show a similar behavior (FIG. 10j).

Plain MAPbI₃ films have a reported elastic modulus of ˜22 GPa. The integration of softer PS (with a reported modulus of ˜3-4 GPa) should affect the mechanical properties of the PS-MAPbI₃ films. Measured by nano-indentation, it was seen that as the wt % of PS is increased with respect to the precursor solution the films become softer as schematically shown in FIG. 11a. The elastic modulus for plain MAPbI₃ films measured at indentation depth of ˜75 nm is recorded as ˜23 GPa, this reduces to 19.2 GPa, and 15.4 GPa as the PS content in the precursor solution is increased to 1 wt %, and 7 wt %, respectively. The corresponding hardness values as a function of indentation depths are shown in FIG. 11f. The ability to modulate the mechanical properties of these films has direct implications for their use in electro-mechanical and opto-mechanical devices. In the current disclosure, this attribute was taken into consideration when manufacturing tunable range pressure sensors that are also combined with the light harvesting properties of these films resulting in light powered tunable pressure sensors. The concept is based on modulating the interface between the ZnO nanosheets and the PS-MAPbI₃ films due to an applied pressure (FIG. 10f). The response of a 1 wt % PS-MAPbI₃ film under 1.0 sun illumination to applied pressure after poling at 5 V/μm is shown in FIG. 11b, where a direct correlation between J_{sc} and the applied pressure is observed. The derivative of current density and pressure shown in FIG. 11c further illustrates that the current accurately tracks the changes in applied pressure both in magnitude and rate. The response from the sensor is correlated to the magnitude of the applied pressure as seen in cycling at different pressure loads of FIG. 11d. Further, the sensor is highly stable as there is no loss in response over more than 200 rapid loading cycles (FIG. 11e).

Varying the PS content in the PS-MAPbI₃ films directly affects its functioning as a pressure sensor due to the change in its mechanical modulus. This is confirmed by observing the response of PS-MAPbI3 films with varying amounts of PS in the precursor solution (FIG. 12a). Two effects are observed; first, as the PS content increases the dynamic range for pressure sensing increases, second, however, the sensitivity does not follow a monotonic trend. Plain MAPbI₃ films are limited to ˜100 kPa pressure range before saturation in J_{sc} is observed. Introducing PS increases the dynamic range of the device progressively to more than 400 kPa with 7 wt % PS-MAPbI₃ films. A high or maximum sensitivity in response is, however, observed for the 1 wt % PS-MAPbI₃ films, as seen in FIG. 12b. At a high or maximum poling fields of 5 V/μm, the 1 wt % PS-MAPbI₃ devices attain a high sensitivity of 19.77 kPa-1 (with a linear response upto 333 kPa), which is 30 times more than the maximum sensitivity possible with the plain MAPbI₃ films (0.64 kPa-1) (FIG. 12c). Further, the 1 wt % PS-MAPbI₃ device can sense pressure as low as 4 Pa (50 μL water droplet) as shown in FIG. 12f. A softer perovskite film due to the incorporated polymer is better able to dissipate the mechanical energy and hence extend the operating pressure range of these devices. At the same time due to an improved poling effect, the incorporation of the polymer also increases the sensitivity and linearity range of the PS-MAPbI₃ films compared to plain MAPbI₃ films. This allows the operating range, sensitivity, and linear range of these pressure sensors to be tuned based on the polymer content. Further, the 1 wt % PS-MAPbI₃ device once poled at 5 V/μm for 5 min can be easily operable for more than 120 hours without a power source and after that the device can be repoled to recover the performance (FIG. 12d). The plain MAPbI₃, 3 wt % and 7 wt % PS-MAPbI3 devices are operable only for 48 hours, 72 hours, and 48 hours, respectively (as shown in FIGS. 12g to 12i). An advantage of the pressure sensor synthesized from the PPH of the disclosure is that the pressure sensor exhibits an improved combination of high sensitivity with a linear response over a broad dynamic pressure range, as well as the device can be self-powered. This is shown in FIG. 12 and Table 6 which shows a comparison of the operating voltage, dynamic pressure range, linear sensing response, and sensitivity of different pressure sensors.

TABLE 6

| | | Operating | Pressure | | | |
|---|---|---|---|---|---|---|
| Sensing | | voltage | range | | Sensitivity | |
| principle | Key material | (V) | (kPa) | Linearity | (kPa⁻¹) | Ref. |
| Transistor | ZnO nanosheets and | Self- | 0.004- | Linear | 20 | PPH |
| | PS-MAPbI₃ | powered | 450 | | | |
| Transistor | 3D organic | 80 | 0.016- | Nonlinear | 1.07 | |
| | semiconductor | | 20 | | | |
| | microstructure | | | | | |
| Transistor | Printed SWCNT | 10 | 1- | Linear | 8 | |
| | active-matrix | | 20 | | | |
| | backplane | | | | | |
| Transistor | Silver nanowires | 1 | 0.0009- | Linear upto | 9.9 (<0.6 | |
| | embedded | | 6.6 | 0.6 kPa | kPa)-0.6 | |
| | PDMS electrode | | | | (0.6-6.6 | |
| | | | | | kPa) | |
| Transistor | Indium-gallium-zinc | 4 | 5- | Linear | 43.6 (50 | |
| | oxide and | | 50 | | kPa) | |
| | polyurethane | | | | | |
| Transistor | Graphene with air- | 25 | 0.25- | Linear upto | 2.05 × 10⁻⁴ | |
| | dielectric layers | | 3000 | 500 kPa | (<500 kPa)- | |
| | | | | | 9.43 × 10⁻⁶ | |
| | | | | | (500-3000 | |
| | | | | | kPa) | |
| Transistor | Microstructured | 200 | 0.03- | Linear upto | 8.2 (<8 | |
| | PDMS and PII2T-Si | | 55 | 8 kPa | kPa)-0.38 | |
| | | | | | (30-55 kPa) | |
| Transistor | Graphene and ion | 2 | 5- | Linear | 0.12 | |
| | gel | | 40 | | | |
| Piezoresistive | Ultrathin gold | 1.5 | 0.013- | Linear | 1.14 | |
| | nanowires | | 5 | | | |
| Piezoresistive | Graphene- | 1 | 0.009- | Linear upto | 0.26 (<2 | |
| | polyurethane sponge | | 10 | 2 kPa | kPa), 0.03 | |
| | | | | | (2-10 kPa) | |
| Piezoresistive | SWNT and PDMS | 2 | 0.0006- | Linear upto | 1.8 (<0.3 | |
| | | | 1.2 | 0.3 kPa | kPa) | |
| Piezoresistive | Pt-coated polymer | 0.5 | 0.003- | Linear | 11.45 | |
| | nanofibres | | 1.5 | | | |
| Piezoresistive | Hollow-sphere | — | 0.0008- | Linear | 7.7 (0.1 | |
| | polypyrrole structure | | 100 | | kPa), 0.4 (1 | |
| | | | | | kPa), 0.004 | |
| | | | | | (100 kPa) | |
| Piezoresistive | rGO and PDMS | — | 0.016- | Linear upto | 25.1 (<2.6 | |
| | microstructure | | 40 | 2.6 kPa | kPa), 0.45 | |
| | | | | | (2.6-40 kPa) | |
| Piezoresistive | Laser-scribed | — | 5- | Nonlinear | 0.96 (<50 | |
| | graphene | | 113 | | kPa), 0.005 | |
| | | | | | (50-113 | |
| | | | | | kPa) | |
| Piezoresistive | CNT-composite | 10 | 0.0002- | Linear upto | 15.1 (<0.5 | |
| | elastomers | | 59 | 0.5 kPa | kPa) | |
| Piezoresistive | Multilayer | — | 0.0013- | Linear | 47.7 | |
| | Microdome- | | 353 | | | |
| | patterned | | | | | |
| | rGO/PVDF | | | | | |
| | composite | | | | | |
| Piezoelectric | Micropattern PDMS | Self- | 0.0021- | Linear upto | 0.31 (<3.2 | |
| | structures and Ag | powered | 13 | 3.2 kPa | kPa), 0.01 | |
| | nanowires | | | | (3.2-13 kPa) | |
| Piezoelectric | PDMS and PAAm- | Self- | 1.3- | Linear upto | 0.013 (<70 | |
| | LiCl hydrogel | powered | 101.2 | 70 kPa | kPa) | |
| Capacitive | Microstructure-d | 80 | 0.003- | Linear upto | 0.55 (<2 | |
| | PDMS | | 7 | 2 kPa | kPa)-0.15 | |
| | | | | | (2-7 kPa) | |
| Capacitive | Ecoflex dielectric | — | 0.0073- | Linear upto | 0.0224 (<16 | |
| | layer and Ag | | 360 | 16 kPa | kPa), | |
| | electrode | | | | 0.00125 (16- | |
| | | | | | 360 kPa) | |
| Capacitive | Single-layer | — | 0.11- | Linear upto | 0.0093 (<20 | |
| | graphene | | 80 | 20 kPa | kPa)-0.0077 | |
| | | | | | (60-80 kPa) | |
| Capacitive | Graphene | — | 0.5- | Nonlinear | 0.002 | |
| | | | 450 | | | |
| Capacitive | Carbon Nanotube | — | 0.00016- | Linear upto | 0.601 (<5 | |
| | and Ecoflex | | 130 | 5 kPa | kPa), 0.077 | |
| | | | | | (30-130 kPa) | |
| Capacitive | Carbon nanotubes | — | 50- | Linear | 0.23 × 10⁻³ | |
| | | | 900 | | | |

Another advantage of the pressure sensor developed by the PPH of the disclosure is that it is achieved in a simple device structure with the ability to sense both a constant static stimuli and also dynamic stimuli, which is a challenge in many architectures.

In the preceding description, for purposes of explanation, numerous details are set forth in order to provide a thorough understanding of the embodiments. However, it will be apparent to one skilled in the art that these specific details may not be required. In other instances, well-known electrical structures and circuits are shown in block diagram form in order not to obscure the understanding. For example, specific details are not provided as to whether the embodiments described herein are implemented as a software routine, hardware circuit, firmware, or a combination thereof.

The above-described embodiments are intended to be examples only. Alterations, modifications and variations can be effected to the particular embodiments by those of skill in the art without departing from the scope, which is defined solely by the claims appended hereto.

What is claimed is:

1. A method of manufacturing a polymer-perovskite hybrid comprising:
obtaining a pre-cursor solution;
mixing the pre-cursor solution with a polymer solution to generate a mixture; and
synthesizing the mixture to manufacture the polymer-perovskite hybrid.

2. The method of claim 1 wherein obtaining the pre-cursor solution comprises:
obtaining a Lewis acid chemical component liquid solution;
obtaining a cation liquid solution by dissolving a cation component in a liquid; and
mixing the cation liquid solution with the Lewis acid chemical component liquid solution.

3. The method of claim 2 wherein obtaining the Lewis acid chemical component comprises dissolving a Lewis acid in a liquid.

4. The method of claim 2 wherein the Lewis acid is lead iodide, tin chloride, tin iodide, aluminum chloride, aluminum halides, lead bromide or lead chloride.

5. The method of claim 2 wherein the cation component is from methylammonium iodide, methylammonium bromide, cesium iodide or formamidinium iodide or a combination of thereof.

6. The method of claim 1 wherein the polymer is polystyrene, polyvinyl chloride, or polysulfone.

7. The method of claim 6 wherein the polystyrene is polystyrene chains.

8. A method of manufacturing a solar cell comprising:
synthesizing a polymer-perovskite hybrid, the polymer-perovskite hybrid manufactured by:
obtaining a pre-cursor solution;
mixing the pre-cursor solution with a polymer solution to generate a mixture; and
synthesizing the mixture to manufacture the polymer-perovskite hybrid.

9. The method of claim 8 wherein obtaining the pre-cursor solution comprises:
obtaining a Lewis acid chemical component liquid solution;
obtaining a cation liquid solution by dissolving at least one cation component in a liquid; and
mixing the cation liquid solution with the Lewis acid chemical component liquid solution.

10. The method of claim 9 wherein obtaining the Lewis acid chemical component comprises dissolving a Lewis acid in a liquid.

11. The method of claim 9 wherein the Lewis acid is lead iodide, aluminum chloride, aluminum halides, lead bromide, lead chloride, tin iodide, tin chloride or tin bromide.

12. The method of claim 9 wherein the cation component is from methylammonium iodide, methylammonium bromide, cesium iodide or formamidinium iodide or a combination thereof.

13. The method of claim 8 wherein the polymer is polystyrene, polyvinyl chloride, or polysulfone.

14. A polymer-perovskite hybrid comprising:
a polymer;
a Lewis acid chemical component that interacts with the polymer and can cross-link with the polymer; and
a cation component that interacts with n-electrons of the polymer.

15. The polymer-perovskite hybrid of claim 14 wherein the Lewis acid chemical component is lead iodide, lead bromide, lead chloride, tin iodide, tin chloride or tin bromide.

16. The polymer-perovskite hybrid of claim 14 wherein the cation component is a salt cation from methylammonium iodide, methylammonium bromide, cesium iodide or formamidinium iodide.
